(19) United States
(12) Patent Application Publication
(10) Pub. No.: US 2026/0371650 A1
(43) Pub. Date: Nov. 19, 2026

(54) SEMICONDUCTOR DEVICES AND METHODS

(71) Applicant: Taiwan Semiconductor Manufacturing Co., Ltd., Hsinchu (TW)

(72) Inventors: Chun Wei Chen, Hsinchu (TW); Yu-Hsing Lin, Hsinchu (TW); Chien-Chia Cheng, Hsinchu (TW); Yen Chuang, Baoshan Township (TW)

(21) Appl. No.: 19/751,732

(22) Filed: Jul. 23, 2026

Related U.S. Application Data
(63) Continuation of application No. 18/953,325, filed on Nov. 20, 2024.

(51) Int. Cl. H10D 30/67; H10D 64/66; H10P 14/40; H10D 30/01; H10D 30/43; H10D 62/10; H10D 62/83

(52) U.S. Cl. CPC H10D 30/6729; H10D 64/663; H10P 14/40; H10D 30/014; H10D 30/43; H10D 30/6735; H10D 30/6757; H10D 62/121; H10D 62/83

(57) ABSTRACT

A semiconductor device and the method of forming the same are provided. The semiconductor device may include a source/drain region, a composite layer with a modulated doping profile on the source/drain region, and a conductive contact over the composite layer. The composite layer may include a first sublayer on the source/drain region and a second sublayer. The first sublayer may be between the second sublayer and the source/drain region. The first sublayer may comprise a first semiconductor material and a first dopant with a first dopant concentration. The second sublayer may comprise a second semiconductor material and a second dopant with a second dopant concentration. The second dopant may be same as the first dopant, and the second dopant concentration may be different from the first dopant concentration. The conductive contact may be electrically connected to the source/drain region by the composite layer.

### PRIORITY CLAIM AND CROSS-REFERENCE

This application is a continuation of U.S. Patent Application No. 18/953,325, filed on Nov. 20, 2024, which application is incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 6C, 7A, 7B, 7C, 8A, 8B, 8C, 9A, 9B, 9C, 10A, 10B, 10C, 11A, 11B, 11C, 11D, 12A, 12B, 12C, 12D, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, 20C, 21A, 21B, 21C, 22A, 22B, 22C, 23A, 23B, 23C, 24A, 24B, 24C, 25A, 25B, 25C, 26A, 26B, 26C, 27A, 27B, 27C, 27D, 29A, 29B, 29C, 30A, 30B, 30C, 31A, 31B, 31C, 31D, 32A, 32B, 32C, 33A, 33B, 33C, 34A, 34B and 34C are cross-sectional views of intermediate steps in the manufacturing of a semiconductor device, including a nano-FET, in accordance with some embodiments.

FIGS. 228A, 28B and 28C are plots of concentrations of various components of a feature in the semiconductor device, including the nano-FET, in accordance with some embodiments.

FIGS. 35A, 35B, 35C, 36A, 36B and 36C are cross-sectional views of a semiconductor device, including a nano-FET, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide a semiconductor device with a composite layer between an epitaxial source/drain region and a conductive contact and the methods of forming the same. The composite layer may be a semiconductor layer with a modulated doping profile, which may comprise a series of highly doped sublayers and a series of lightly doped sublayers arranged in an alternating pattern. The composite layer may have a high average dopant concentration and a high average carrier concentration, which may reduce the contact resistance between the epitaxial source/drain region and the conductive contact. As a result, the performance of the semiconductor device may be improved.

Some embodiments discussed herein are described in the context of a semiconductor device, such as a super power rail (SPR) device, including a nano-FET. However, various embodiments may be applied to devices including other types of transistors (e.g., fin field effect transistors (FinFETs), vertical field-effect transistors (VFETs), complementary field-effect transistors (CFETs), planar transistors, or the like) in lieu of or in combination with the nano-FETs.

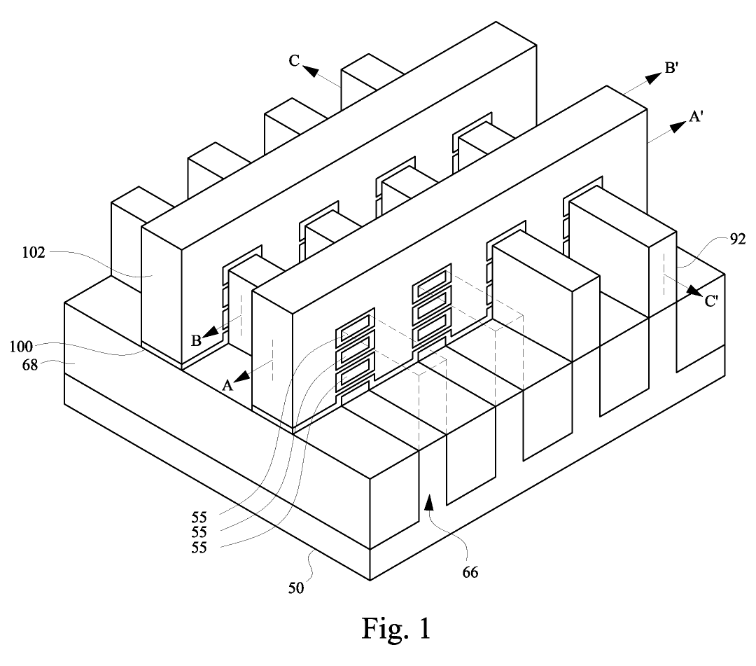

FIG. 1 illustrates an example of nano-FETs (e.g., nanowire FETs, nanosheet FETs, or the like) in a three-dimensional view. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Shallow trench isolation (STI) regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Cross-section A-A’ is along a longitudinal axis of a gate electrode 102 and in a direction, for example, perpendicular to the direction of current flow between the epitaxial source/drain regions 92 of a nano-FET. Cross-section B-B’ is parallel to cross-section A-A’ and extends through epitaxial source/drain regions 92 of multiple nano-FETs. Cross-section C-C’ is perpendicular to cross-section A-A’ and is parallel to a longitudinal axis of a fin 66 of the nano-FET and in a direction of, for example, a current flow between the epitaxial source/drain regions 92 of the nano-FET. Subsequent figures refer to these reference cross-sections for clarity. Some embodiments discussed herein are discussed in the context of nano-FETs formed using a gate-last process. In other embodiments, a gate-first process may be used. Also, some embodiments contemplate aspects used in planar devices, such as planar FETs or in FinFETs.

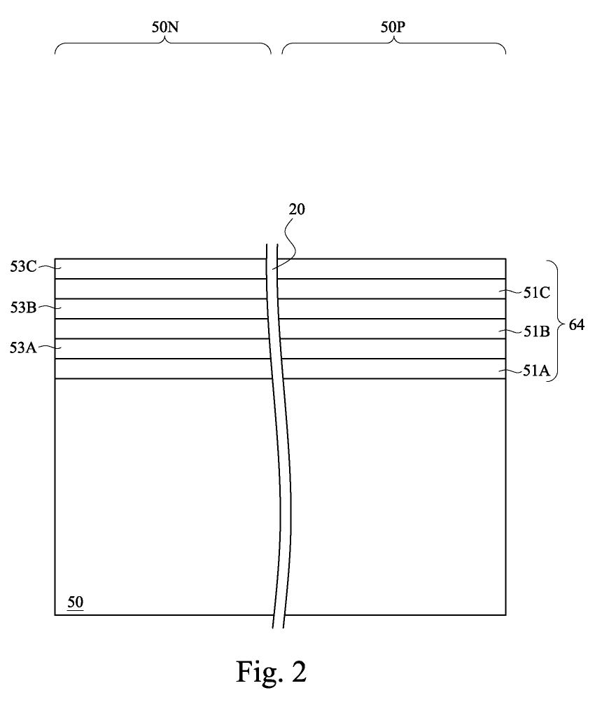

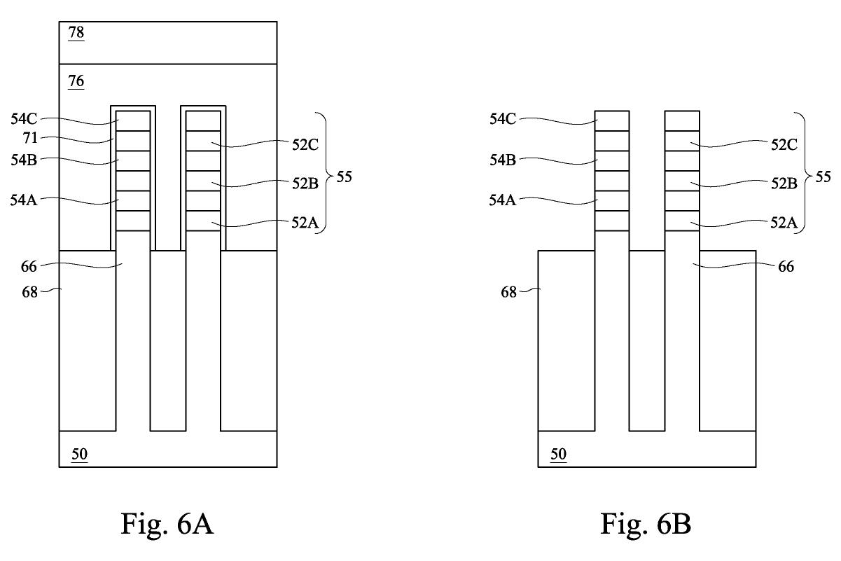

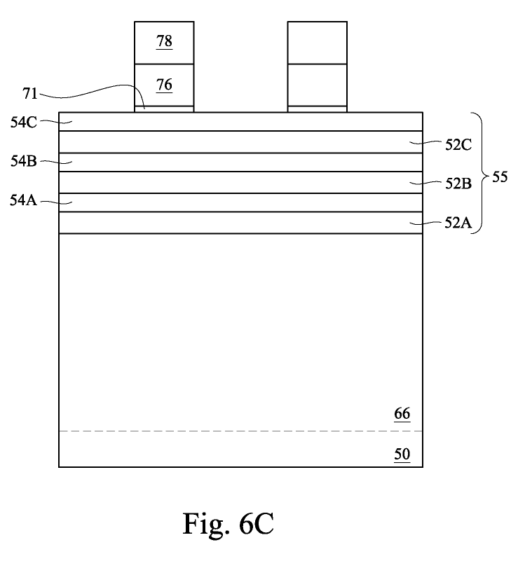

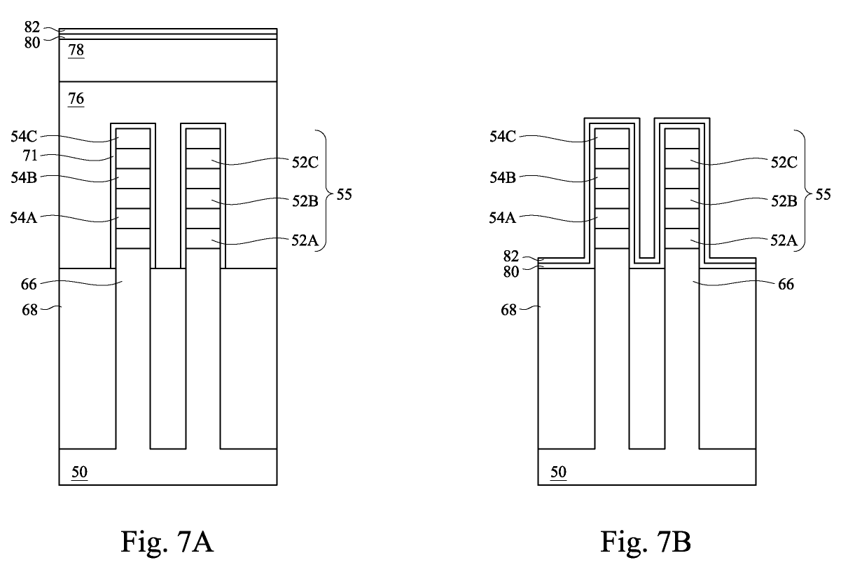

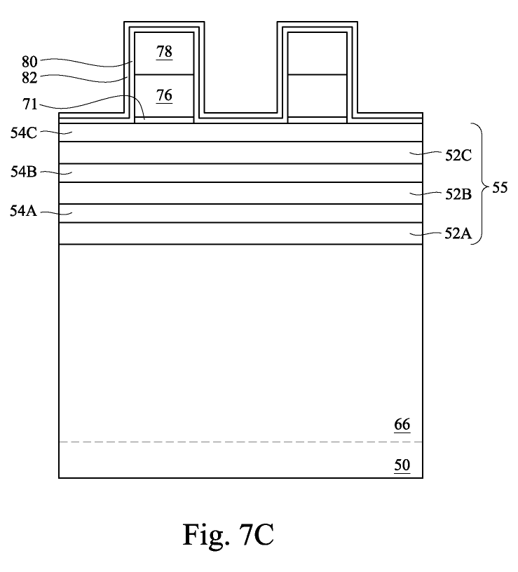

FIGS. 2-34C are cross-sectional views of intermediate steps in the manufacturing of a semiconductor device, including a nano-FET, in accordance with some embodiments. FIGS. 2 through 5, 6A, 7A, 8A, 9A, 10A, 11A, 12A, 13A, 14A, 15A, 16A, 17A, 18A, 19A, 20A, 21A, 22A, 23A, 24A, 25A, 26A, 27A, 29A, 30A, 31A, 32A, 33A and 34A illustrate cross-sectional views along the reference cross-section A-A’ illustrated in FIG. 1. FIGS. 6B, 7B, 8B, 9B, 10B, 11B, 12B, 12D, 13B, 14B, 15B, 16B, 17B, 18B, 19B, 20B, 21B, 22B, 23B, 24B, 25B, 26B, 27B, 29B, 30B, 31B, 32B, 33B and 34B illustrate cross-sectional views along the reference cross-section B-B’ illustrated in FIG. 1. FIGS. 7C, 8C, 9C, 10C, 11C, 11D, 12C, 13C, 14C, 15C, 16C, 17C, 18C, 19C, 20C, 21C, 22C, 23C, 24C, 25C, 26C, 27C, 29C, 30C, 31C, 32C, 33C and 34C illustrate cross-sectional views along the reference cross-section C-C’ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers 51 will be removed and the second semiconductor layers 53 will be patterned to form channel regions of nano-FETs in the n-type region 50N and the p-type region 50P. However, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In some embodiments the second semiconductor layers 53 may be removed and the first semiconductor layers 51 may be patterned to form channel regions of nano-FETs in the n-type region 50N, and the first semiconductor layers 51 may be removed and the second semiconductor layers 53 may be patterned to form channel regions of nano-FETs in the p-type region 50P. In some embodiments, the second semiconductor layers 53 may be removed and the first semiconductor layers 51 may be patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material different from the first semiconductor material, such as silicon, carbon-doped silicon, or the like.

The first semiconductor materials and the second semiconductor materials may be materials having a high etch selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

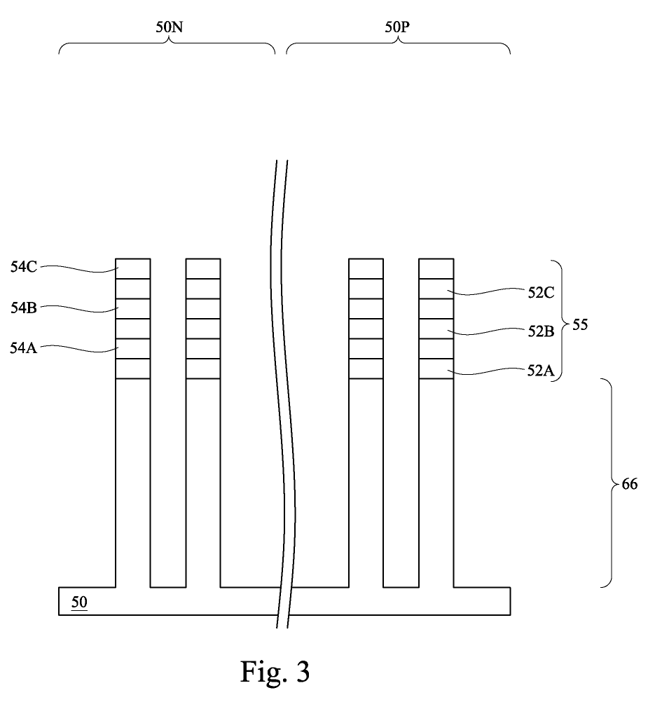

In FIG. 3, fins 66 (e.g., protrusions or base portions) are formed. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

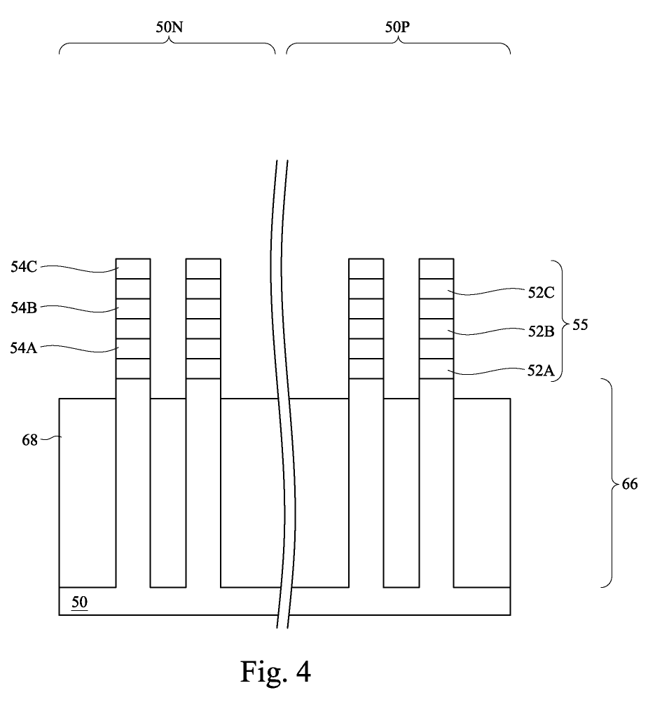

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2-4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an annealing may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

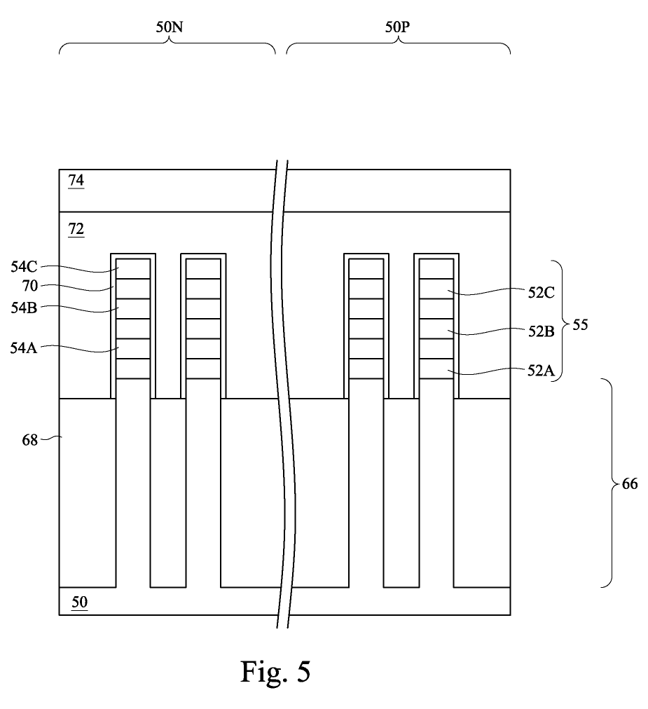

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A-20C illustrate additional steps in the manufacturing of semiconductor device, including a nano-FET. The intermediate steps described in FIGS. 6A-20C may be applied to both the n-type region 50N and the p-type region 50P. In FIGS. 6A-6C, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 7A-7C, a first spacer layer 80 and a second spacer layer 82 are formed over the structures illustrated in FIGS. 6A-6C. The first spacer layer 80 and the second spacer layer 82 will be subsequently patterned to act as spacers for forming self-aligned source/drain regions. In FIGS. 7A-7C, the first spacer layer 80 is formed on top surfaces of the STI regions 68; top surfaces and sidewalls of the nanostructures 55, and the masks 78; and sidewalls of the fins 66, the dummy gates 76, and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1x10¹⁵ atoms/cm³ to about 1x10¹⁹ atoms/cm³. An annealing may be used to repair implant damage and to activate the implanted impurities.

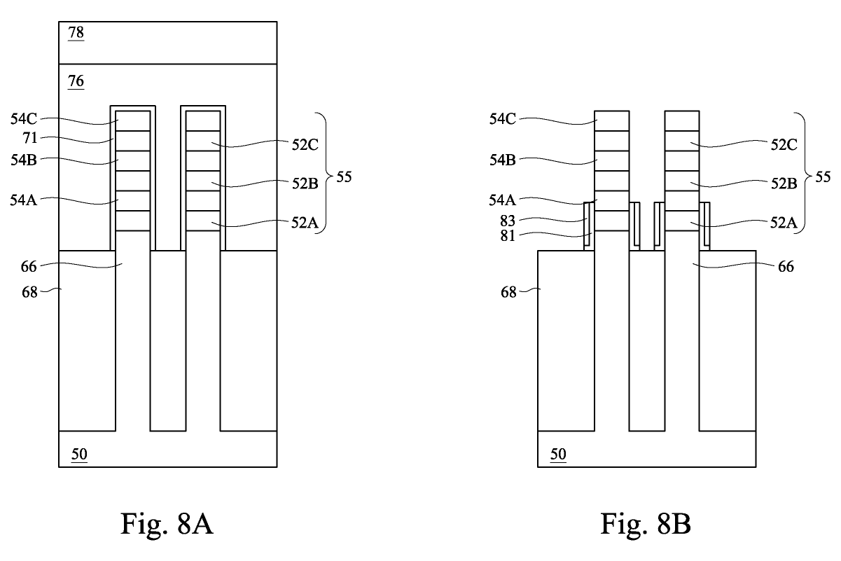

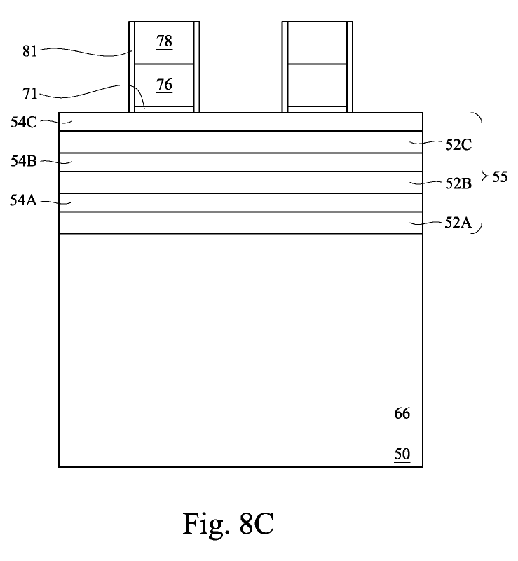

In FIGS. 8A-8C, the first spacer layer 80 and the second spacer layer 82 are etched to form first spacers 81 and second spacers 83. As will be discussed in greater detail below, the first spacers 81 and the second spacers 83 act to self-aligned subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8B. Thereafter, the second spacers 83 act as a mask while etching exposed portions of the first spacer layer 80, thereby forming first spacers 81 as illustrated in FIG. 8B and 8C.

As illustrated in FIG. 8B, the first spacers 81 and the second spacers 83 are disposed on sidewalls of the fins 66 and/or nanostructures 55. As illustrated in FIG. 8C, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy gate dielectrics 71. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

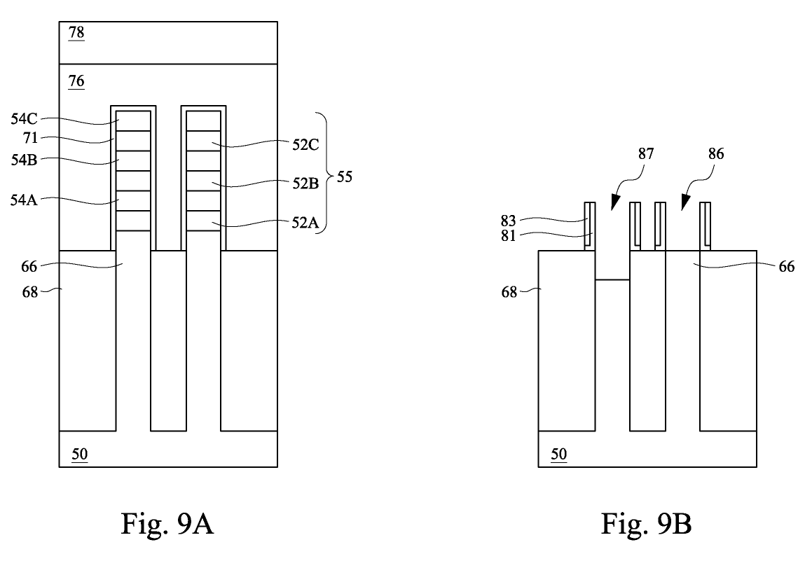

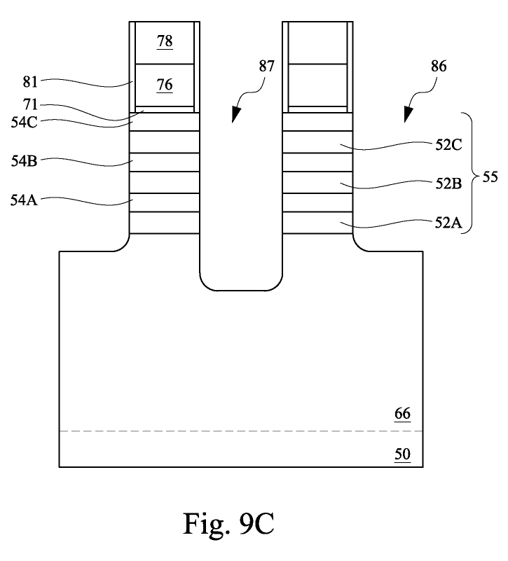

In FIGS. 9A-9C, first recesses 86 and second recesses 87 are formed in the fins 66, the nanostructures 55, and the substrate 50, in accordance with some embodiments. Epitaxial source/drain regions will be subsequently formed in the first recesses 86 and semiconductor layer (e.g., a sacrificial material) and epitaxial source/drain regions will be subsequently formed in the second recesses 87. The first recesses 86 and the second recesses 87 may extend through the first nanostructures 52 and the second nanostructures 54, and into the substrate 50. As illustrated in FIG. 9B, top surfaces of the STI regions 68 may be level with bottom surfaces of the first recesses 86. In various embodiments, the fins 66 may be etched such that bottom surfaces of the first recesses 86 are disposed below the top surfaces of the STI regions 68 or the like. Bottom surfaces of the second recesses 87 may be disposed below the bottom surfaces of the first recesses 86 and the top surfaces of the STI regions 68. The first recesses 86 and the second recesses 87 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 86 and the second recesses 87. A single etch process or multiple etch processes may be used to etch each layer of the nanostructures 55 and/or the fins 66. Timed etch processes may be used to stop the etching after the first recesses 86 and the second recesses 87 reach desired depths. The second recesses 87 may be etched by the same processes used to etch the first recesses 86 and an additional etch process before or after the first recesses 86 are etched. In some embodiments, regions corresponding to the first recesses 86 may be masked while the additional etch process for the second recesses 87 is performed.

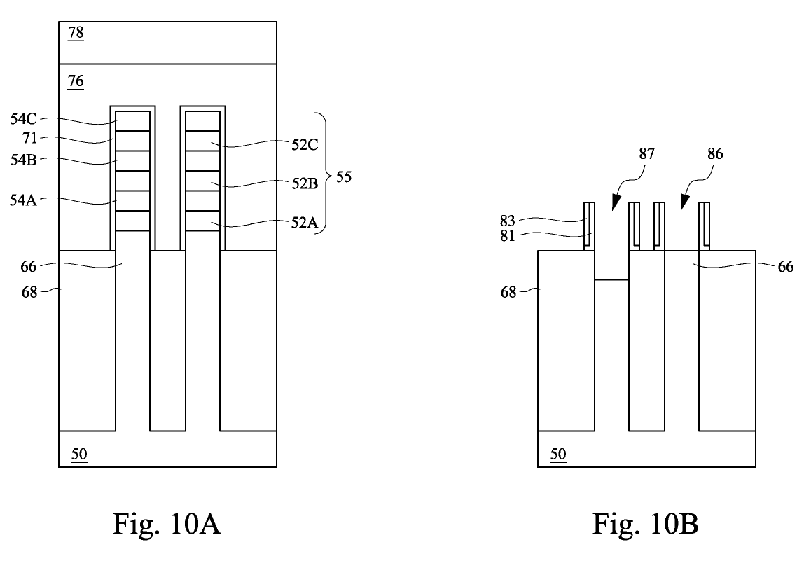

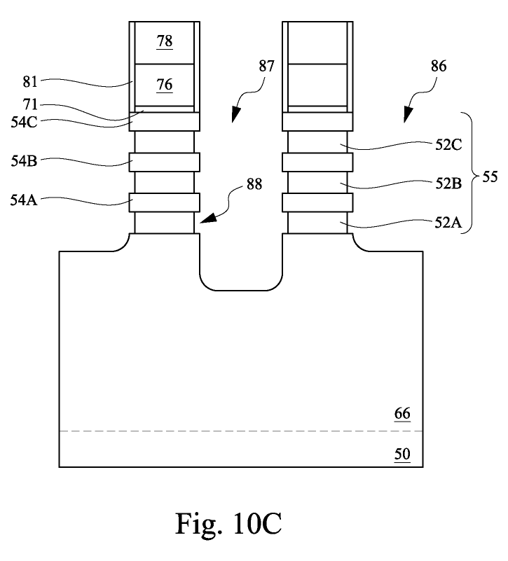

In FIGS. 10A-10C, portions of sidewalls of the nanostructures 55 formed of the first semiconductor materials (e.g., the first nanostructures 52) exposed by the first recesses 86 and the second recesses 87 are etched to form sidewall recesses 88. Although sidewalls of the first nanostructures 52 adjacent the sidewall recesses 88 are illustrated as being straight in FIG. 10C, the sidewalls may be concave or convex. The sidewalls may be etched using isotropic etching processes, such as wet etching or the like. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52.

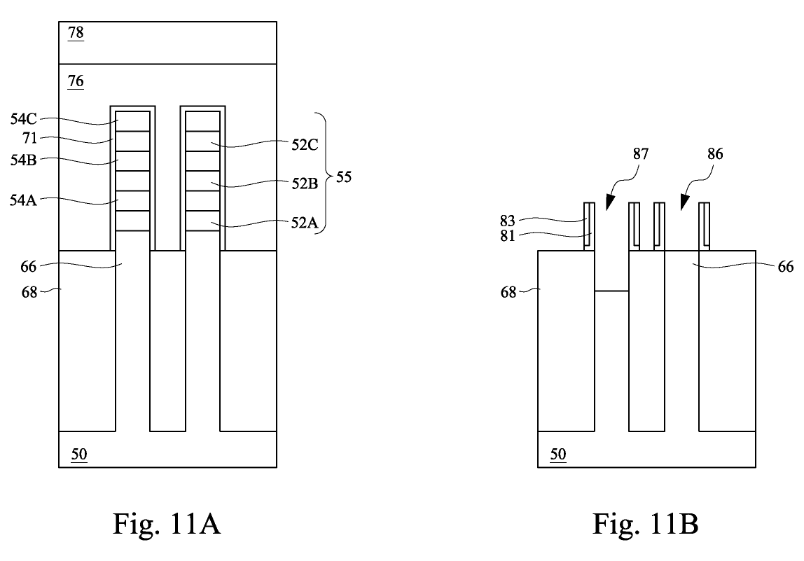

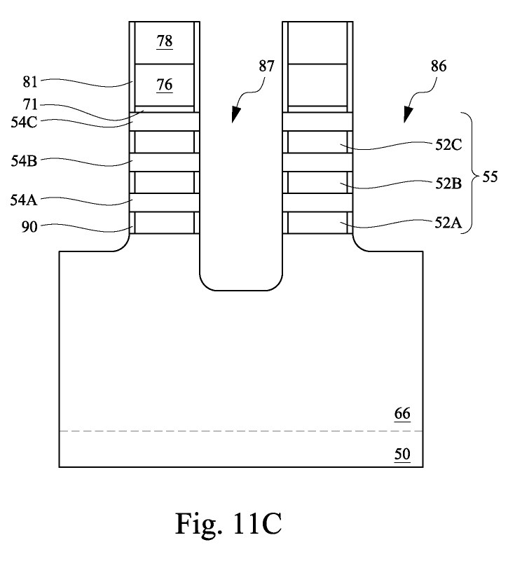

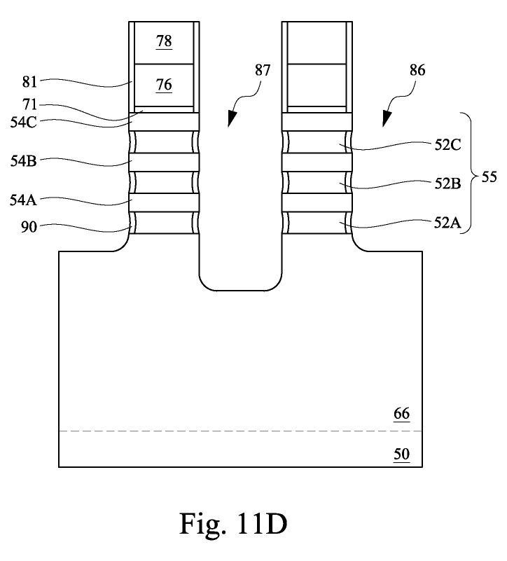

In FIGS. 11A-11D, first inner spacers 90 are formed in the sidewall recess 88. The first inner spacers 92 may be formed by depositing an inner spacer layer (not separately illustrated) over the structures illustrated in FIGS. 10A-10C. The first inner spacers 92 act as isolation features between subsequently formed source/drain regions and a gate structure. As will be discussed in greater detail below, source/drain regions and epitaxial materials will be formed in the first recesses 86 and the second recesses 87, while the first nanostructures 52 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54, the outer sidewalls of the first inner spacers 90 may extend beyond or be recessed from sidewalls of the second nanostructures 54.

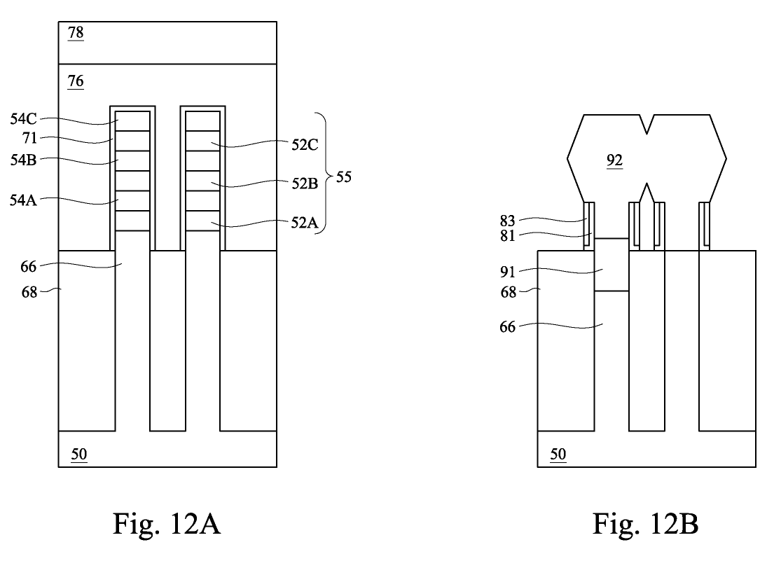

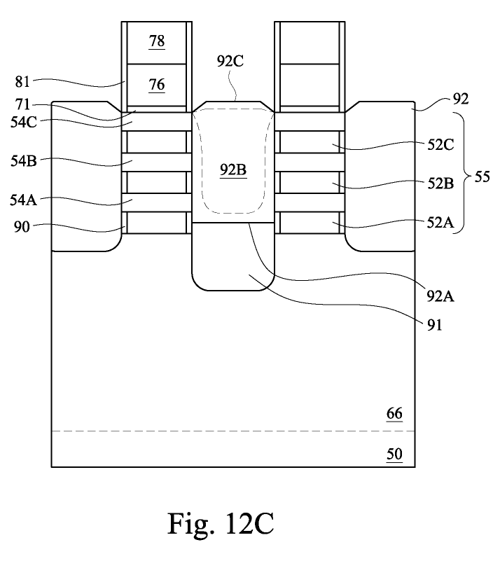

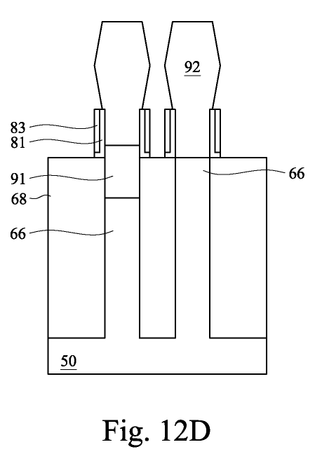

Moreover, although the outer sidewalls of the first inner spacers 90 are illustrated as being straight in FIG. 11C, the outer sidewalls of the first inner spacers 90 may be concave or convex. As an example, FIG. 11D illustrates an embodiment in which sidewalls of the first nanostructures 52 are concave, outer sidewalls of the first inner spacers 90 are concave, and the first inner spacers 90 are recessed from sidewalls of the second nanostructures 54. The inner spacer layer may be etched by an anisotropic etching process, such as RIE, NBE, or the like. The first inner spacers 92 may be used to prevent damage to subsequently formed source/drain regions (such as the epitaxial source/drain regions 92, discussed below with respect to FIGS. 12A-12D) by subsequent etching processes, such as etching processes used to form gate structures.

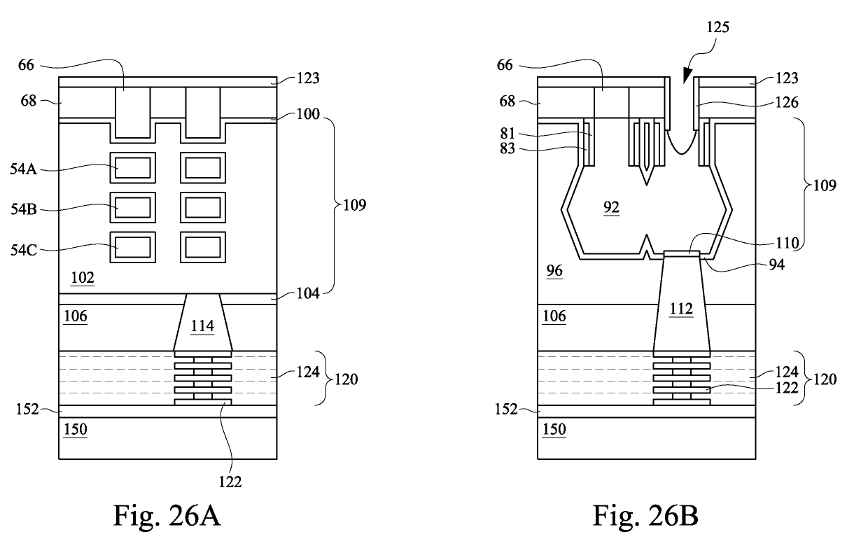

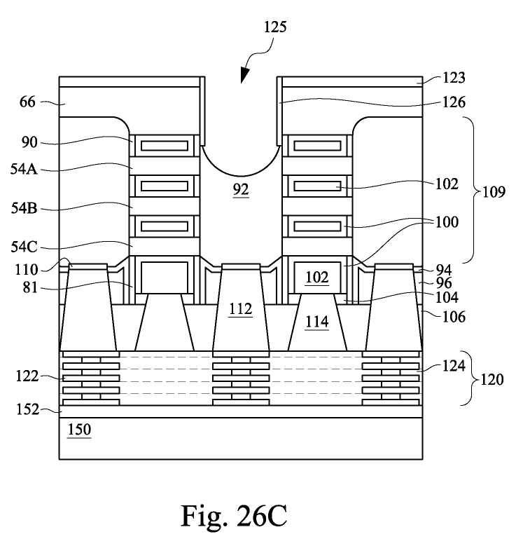

In FIGS. 12A-12D, semiconductor layer 91 is formed in the second recesses 87 and epitaxial source/drain regions 92 are formed in the first recesses 86 and the second recesses 87. In some embodiments, the semiconductor layer 91 may be sacrificial materials, which are subsequently removed to form back-side vias (such as the back-side vias 130, discussed below with respect to FIGS. 26A-26D). The semiconductor layer 91 may be epitaxially grown in the second recesses 87 using a process such as CVD, ALD, VPE, MBE, or the like. The semiconductor layer 91 may include any acceptable material, such as silicon germanium or the like. The semiconductor layer 91 may be formed of materials having high etch selectivity to materials of the epitaxial source/drain regions 92, the substrate 50, and dielectric layers (such as the STI regions 6). As such, the semiconductor layer 91 may be removed and replaced with the back-side vias without significantly removing the epitaxial source/drain regions 92 and the dielectric layers. In embodiments where the semiconductor layer 91 and the epitaxial source/drain regions 92 each comprise silicon germanium, a germanium percentage of the semiconductor layer 91 may be different than a germanium percentage of the epitaxial source/drain region so that etching selectivity may be achieved. The semiconductor layer 91 may be selectively grown in the first recesses 86 by masking the second recesses 87 while the semiconductor layer 91 is grown, for example.

The epitaxial source/drain regions 92 are then formed in the first recesses 86 and over the semiconductor layer 91 in the second recesses 87. In some embodiments, the epitaxial source/drain regions 92 may exert stress on the second nanostructures 54, thereby improving performance. As illustrated in FIG. 12C, the epitaxial source/drain regions 92 are formed in the first recesses 86 and the second recesses 87 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 92 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 and the second recesses 87 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorus doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 and the second recesses 87 in the p-type region 50P. The epitaxial source/drain regions 92 may include any acceptable material appropriate for p-type nano-FETs. For example, if the first nanostructures 52 are silicon germanium, the epitaxial source/drain regions 92 may comprise materials exerting a compressive strain on the first nanostructures 52, such as silicon germanium, boron doped silicon germanium, germanium, germanium tin, or the like. The epitaxial source/drain regions 92 may also have surfaces raised from respective surfaces of the multi-layer stack 56 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The epitaxial source/drain regions 92 may have an impurity concentration of between about 1 x 10¹⁹ atoms/cm³ and about 1 x 10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 12B. In other embodiments, adjacent epitaxial source/drain regions 92 remain separated after the epitaxy process is completed as illustrated by FIG. 12D. In the embodiments illustrated in FIGS. 12B and 12D, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

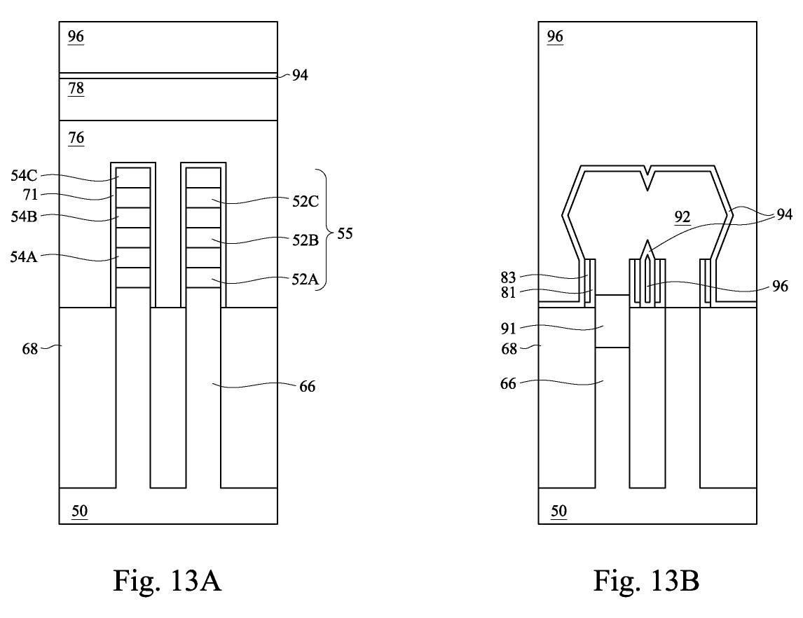

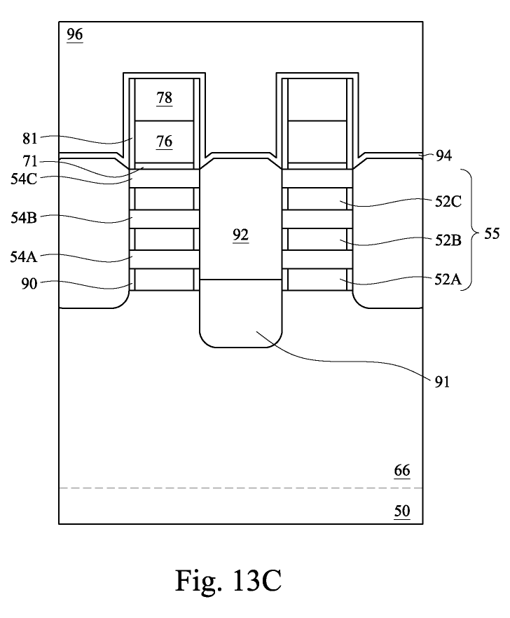

In FIGS. 13A-13C, a first interlayer dielectric (ILD) 96 is deposited over the structure illustrated in FIGS. 12A-12C. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96.

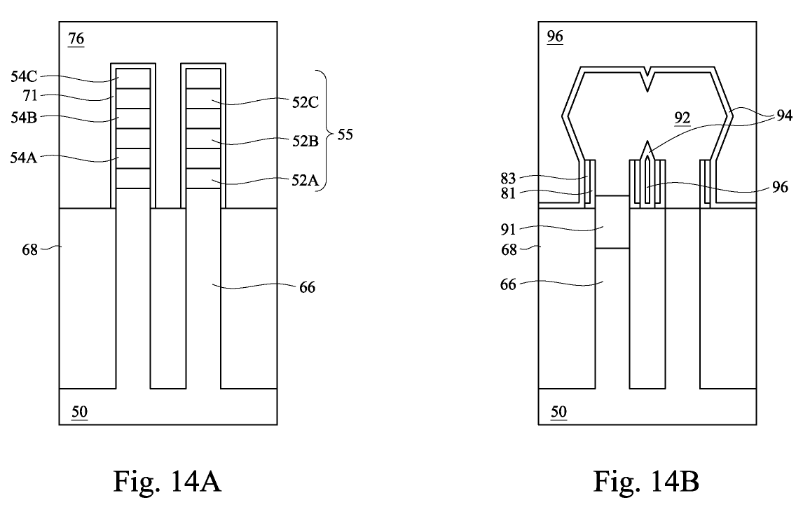

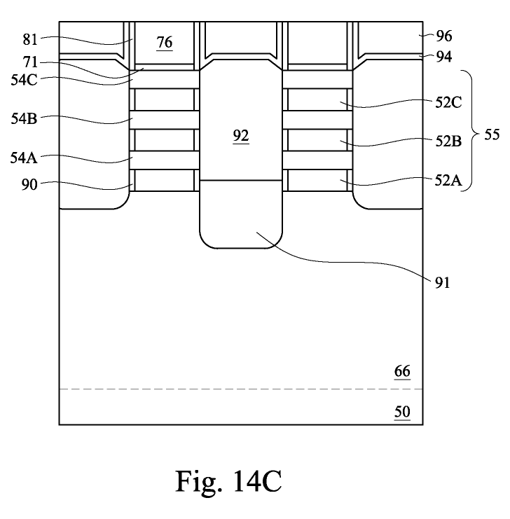

In FIGS. 14A-14C, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the first spacers 81.

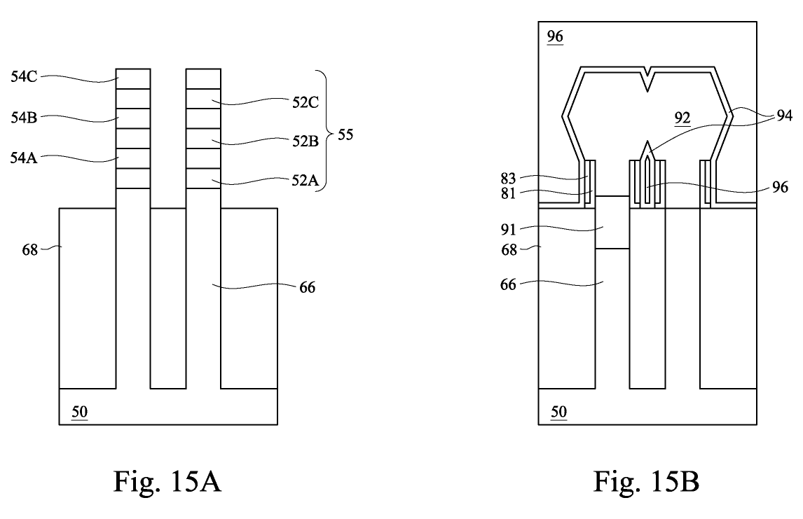

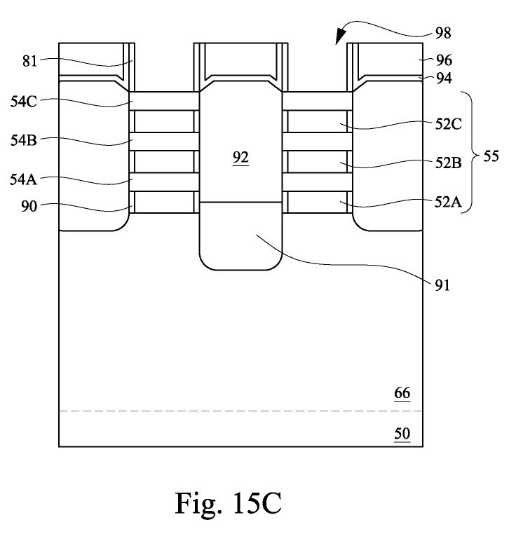

In FIGS. 15A-15C, the dummy gates 76, and the masks 78 if present, are removed in one or more etching steps, so that third recesses 98 are formed. Portions of the dummy gate dielectrics 60 in the third recesses 98 are also be removed. In some embodiments, the dummy gates 76 and the dummy gate dielectrics 60 are removed by an anisotropic dry etch process. For example, the etching process may include a dry etch process using reaction gas(es) that selectively etch the dummy gates 76 at a faster rate than the first ILD 96 or the first spacers 81. Each of the third recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 60 may be used as etch stop layers when the dummy gates 76 are etched. The dummy gate dielectrics 60 may then be removed after the removal of the dummy gates 76.

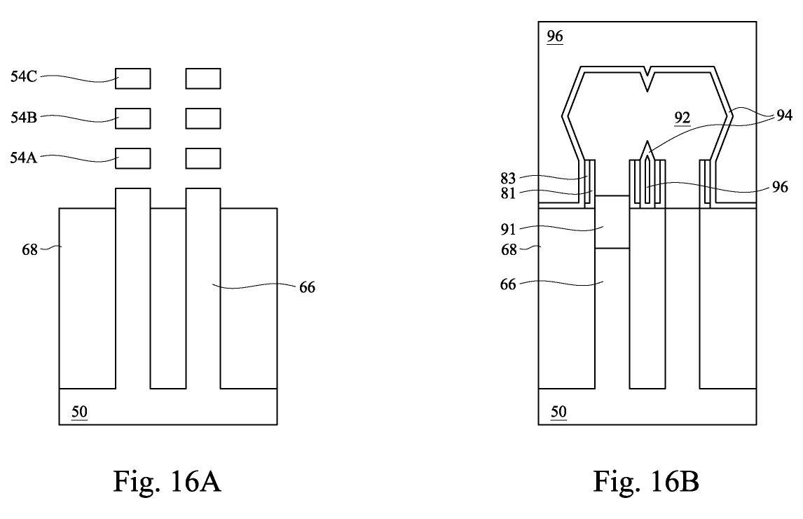

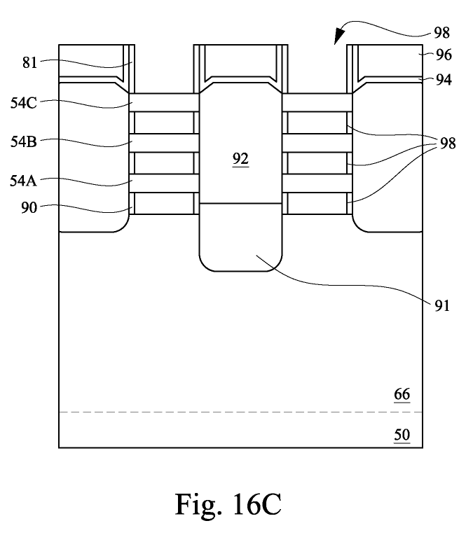

In FIGS. 16A-16C, the first nanostructures 52 are removed extending the third recesses 98. The first nanostructures 52 may be removed by performing an isotropic etching process such as wet etching or the like using etchants which are selective to the materials of the first nanostructures 52, while the second nanostructures 54, the substrate 50, the STI regions 68 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52.

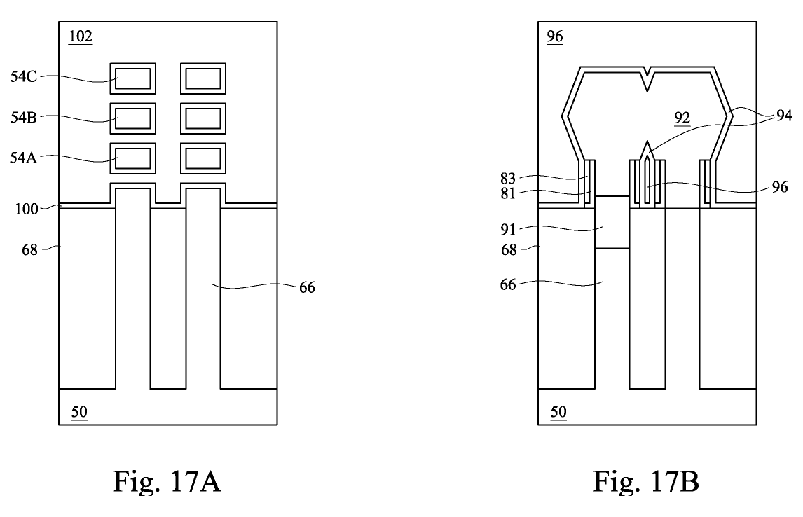

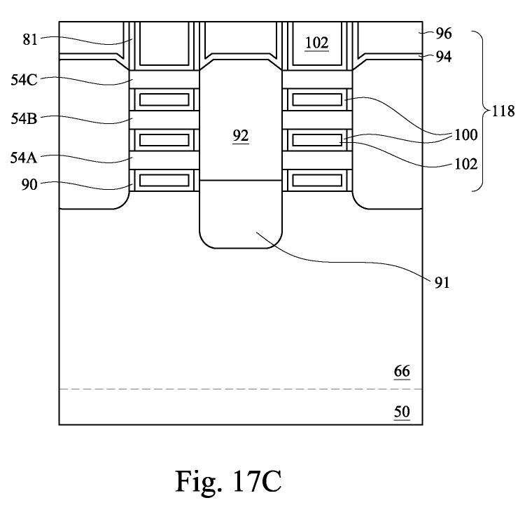

In FIGS. 17A-17C, gate dielectric layers 100 and gate electrodes 102 are formed for replacement gates. The gate dielectric layers 100 are deposited conformally in the third recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the first spacers 81, and the STI regions 68 and on sidewalls of the first spacers 81 and the first inner spacers 90.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a dielectric constant (k) value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the third recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A-17C, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the third recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

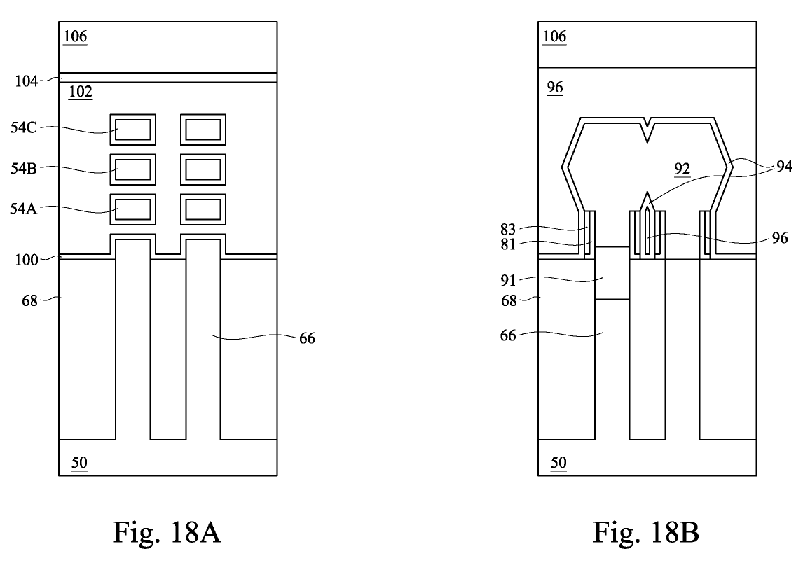

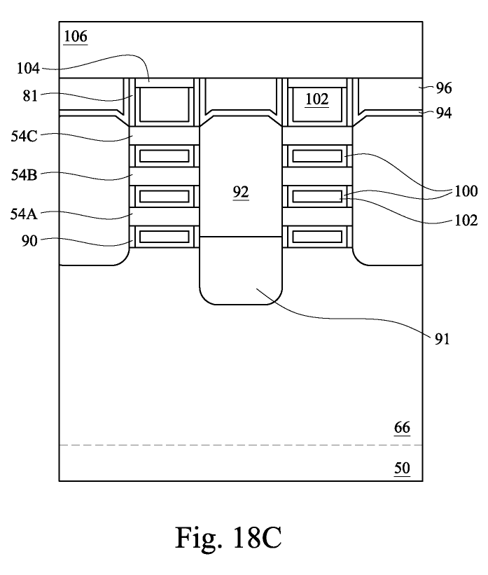

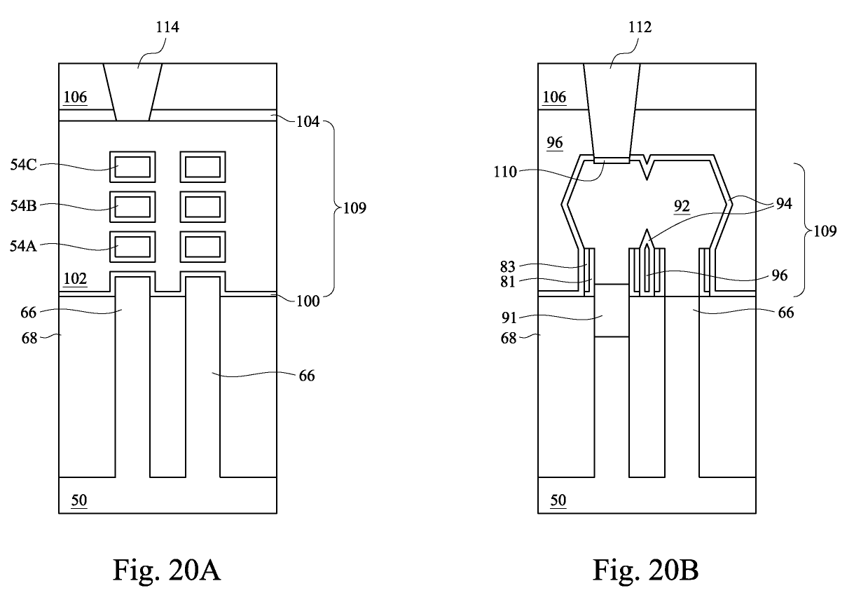

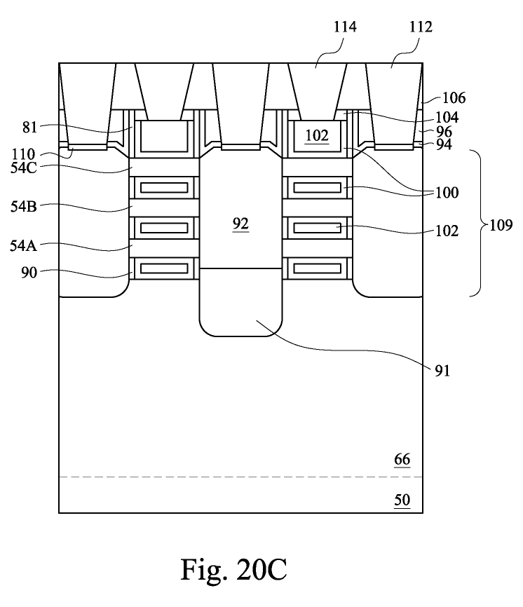

In FIGS. 18A-18C, the gate structures (including the gate dielectric layers 100 and the corresponding overlying gate electrodes 102) are recessed, so that recess are formed directly over the gate structures and between opposing portions of first spacers 81. Gate masks 104 comprising one or more layers of dielectric material, such as silicon nitride, silicon oxynitride, or the like, are filled in the recesses, followed by a planarization process to remove excess portions of the dielectric material extending over the first ILD 96. Subsequently formed gate contacts (such as the gate contacts 114, discussed below with respect to FIGS. 20A-20C) penetrate through the gate masks 104 to contact the top surfaces of the recessed gate electrodes 102.

As further illustrated by FIGS. 18A-18C, a second ILD 106 is deposited over the first ILD 96 and over the gate masks 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

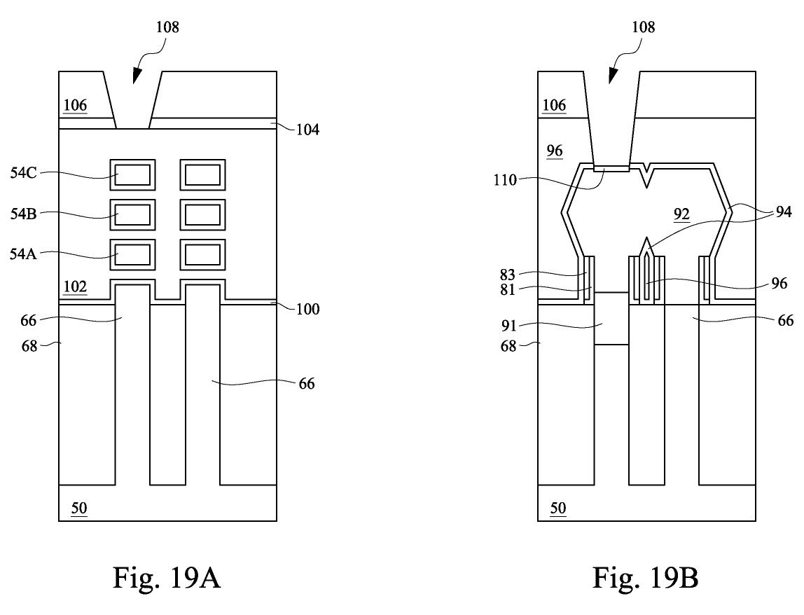

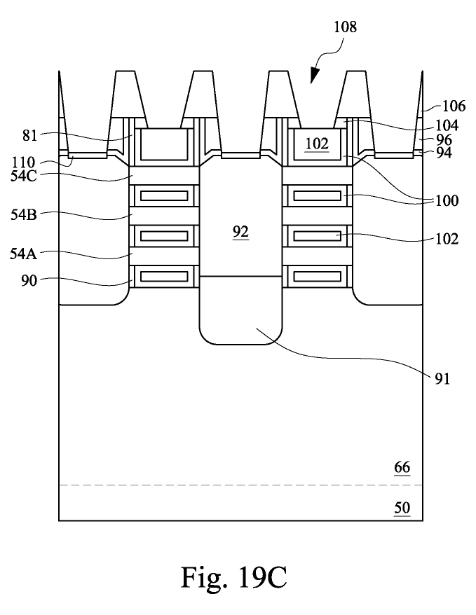

In FIGS. 19A-19C, the second ILD 106, the first ILD 96, the CESL 94, and the gate masks 104 are etched to form fourth recesses 108 exposing surfaces of the epitaxial source/drain regions 92 and/or the gate structures. The fourth recesses 108 may be formed by etching using an anisotropic etching process, such as RIE, NBE, or the like. In some embodiments, the fourth recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the fourth recesses 108 extend into the epitaxial source/drain regions 92 and/or the gate structures, and a bottom of the fourth recesses 108 may be level with (e.g., at a same level, or having a same distance from the substrate 50), or lower than (e.g., closer to the substrate 50) the epitaxial source/drain regions 92 and/or the gate structures. Although FIG. 19C illustrates the fourth recesses 108 as exposing the epitaxial source/drain regions 92 and the gate structures in a same cross-section, in various embodiments, the epitaxial source/drain regions 92 and the gate structures may be exposed in different cross-sections, thereby reducing the risk of shorting subsequently formed contacts.

After the fourth recesses 108 are formed, first silicide regions 110 are formed over the epitaxial source/drain regions 92. In some embodiments, the first silicide regions 110 are formed by first depositing a metal layer (not separately illustrated) on the exposed portions of the epitaxial source/drain regions 92. The material of the metal layer may be capable of reacting with the semiconductor materials of the underlying epitaxial source/drain regions 92 (e.g., silicon, silicon germanium, germanium) to form silicide or germanide materials, such as nickel, cobalt, titanium, tantalum, platinum, tungsten, other noble metals, other refractory metals, rare earth metals, or their alloys. Then a thermal annealing process may be performed to convert portions of the epitaxial source/drain regions 92 in contact with the metal layer and portions of the metal layer in contact with the epitaxial source/drain regions 92 into the first silicide regions 110. The remaining portions of the metal layer may be then removed by a suitable etching process. Although the first silicide regions 110 are referred to as silicide regions, the first silicide regions 110 may also be germanide regions, or silicon germanide regions (e.g., regions comprising silicide and germanide).

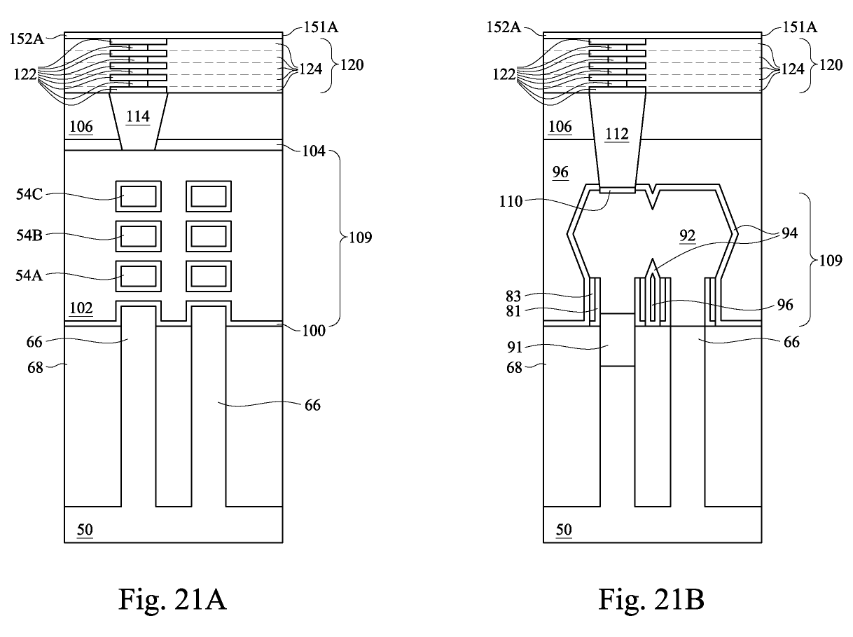

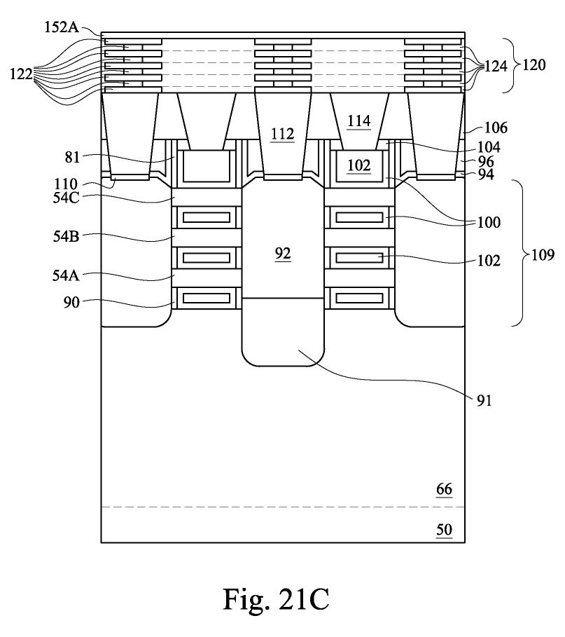

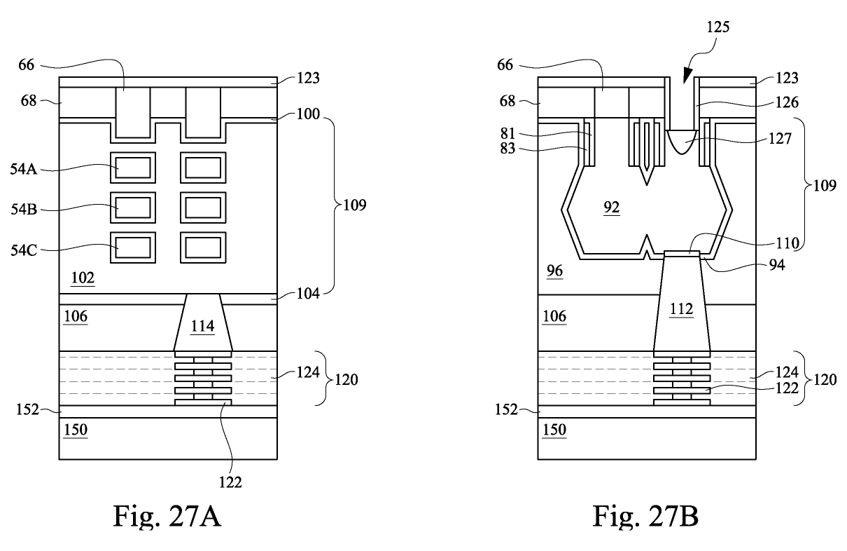

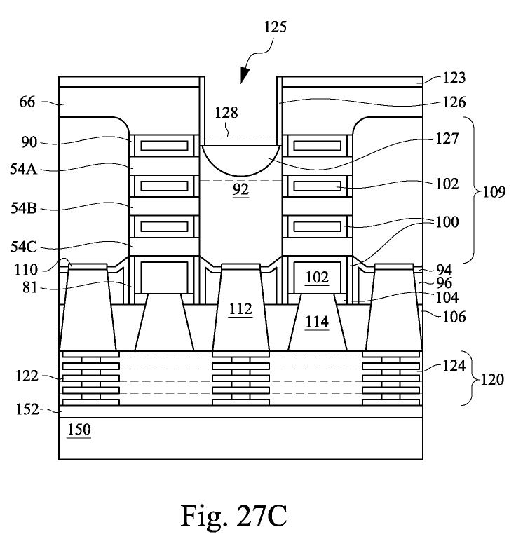

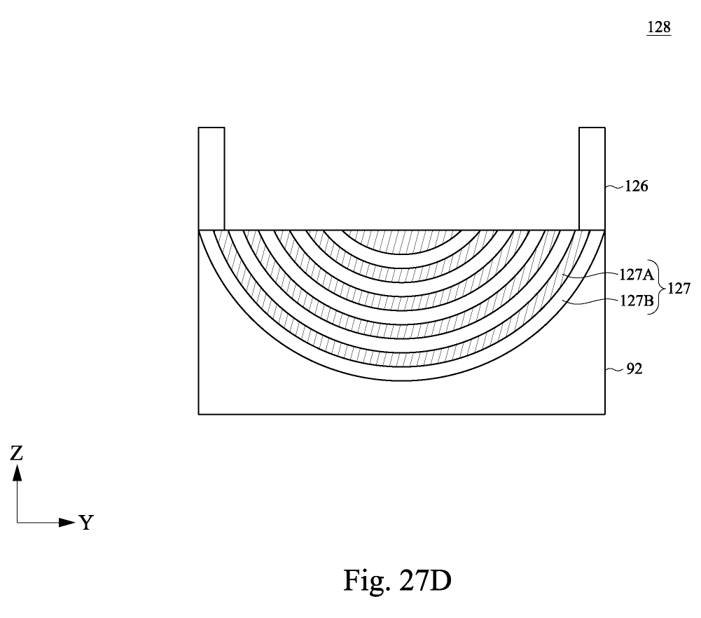

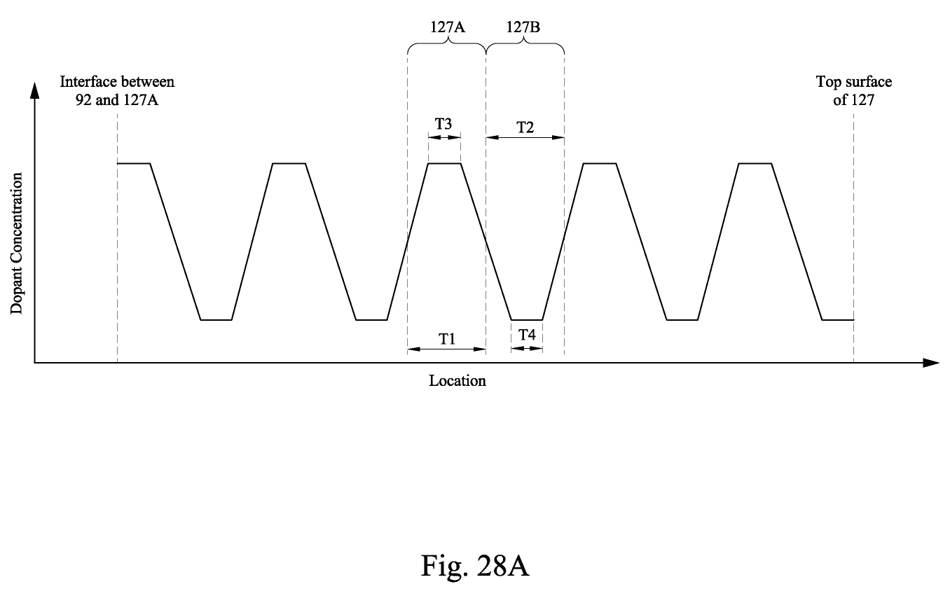

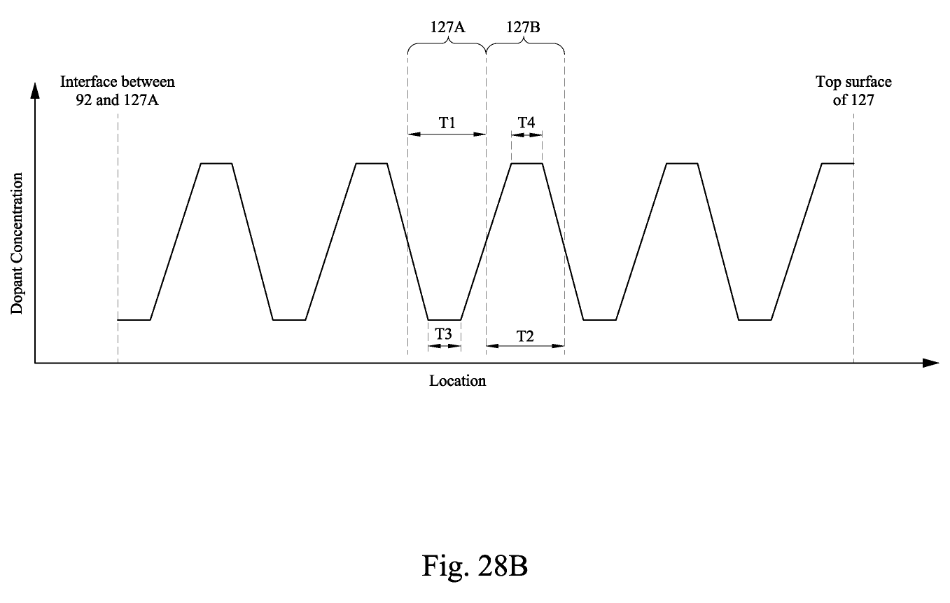

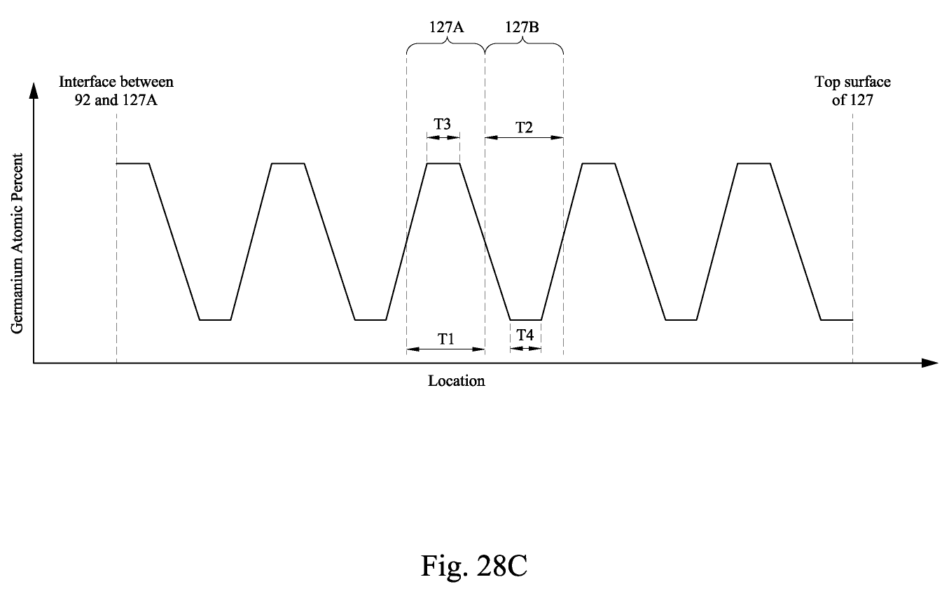

In FIGS. 20A-20C, source/drain contacts 112 and gate contacts 114 (also referred to as contact plugs) are formed in the fourth recesses 108. The source/drain contacts 112 and the gate contacts 114 may each comprise one or more layers, such as barrier layers, diffusion layers, and fill materials. For example, in some embodiments, the source/drain contacts 112 and the gate contacts 114 each include a barrier layer and a conductive material, and are each electrically connected to an underlying conductive feature (e.g., a gate electrode 102 and/or a first silicide region 110). The gate contacts 114 are electrically connected to the gate electrodes 102 and the source/drain contacts 112 are electrically connected to the first silicide regions 110. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from surfaces of the second ILD 106. The epitaxial source/drain regions 92, the second nanostructures 54 (e.g., channel regions), and the gate structures (including the gate dielectric layers 100 and the gate electrodes 102) may collectively be referred to as transistor structures 109. The transistor structures 109 may be collectively disposed in a device layer, with a first interconnect structure (such as a front-side interconnect structure 120, discussed below with respect to FIGS. 21A-21C) being formed over front-sides of the transistor structures 109 and a second interconnect structure (such as a back-side interconnect structure 136, discussed below with respect to FIGS. 27A-28C) being formed over back-sides of the transistor structures 109. Although the device layer is described as having nano-FETs, other embodiments may include a device layer having different types of transistors (e.g., planar FETs, finFETs, thin film transistors (TFTs), or the like).

Although FIGS. 20A-20C illustrate a source/drain contact 112 extending to each of the epitaxial source/drain regions 92, the source/drain contacts 112 may be omitted from certain ones of the epitaxial source/drain regions 92. For example, as explained in greater detail below, conductive features (e.g., back-side vias or power rails) may be subsequently attached through a back-side of one or more of the epitaxial source/drain regions 92. For these particular epitaxial source/drain regions 92, the source/drain contacts 112 may be omitted or may be dummy contacts that are not electrically connected to any overlying conductive lines (such as the first conductive features 122, discussed below with respect to FIGS. 21A-21C).

FIGS. 21A-34C illustrate intermediate steps of forming front-side interconnect structures and back-side interconnect structures on the transistor structures 109. The front-side interconnect structures and the back-side interconnect structures may each comprise conductive features that are electrically connected to the nano-FETs formed on the substrate 50 to provide functional circuits. The intermediate steps described in FIGS. 21A-34C may be applied to both the n-type region 50N and the p-type region 50P, unless noted otherwise. As noted above, a back-side conductive feature (e.g., a back-side via or a power rail) may be connected to one or more of the epitaxial source/drain regions 92. As such, the source/drain contacts 112 may be optionally omitted from these epitaxial source/drain regions 92.

In FIGS. 21A-21C, the front-side interconnect structure 120 is formed on the second ILD 106. The front-side interconnect structure 120 may be referred to as a front-side interconnect structure because it is formed on a front-side of the transistor structures 109 (e.g., a side of the transistor structures 109 on which active devices are formed). The front-side interconnect structure 120 may comprise one or more layers of first conductive features 122 formed in one or more stacked first dielectric layers 124. Each of the stacked first dielectric layers 124 may comprise a dielectric material, such as a low-k dielectric material, an extra low-k (ELK) dielectric material, or the like. The first dielectric layers 124 may be deposited using an appropriate process, such as, CVD, ALD, PVD, PECVD, or the like. The first conductive features 122 may comprise conductive lines and conductive vias interconnecting the layers of conductive lines. The conductive vias may extend through respective ones of the first dielectric layers 124 to provide vertical connections between layers of the conductive lines. The first conductive features 122 may be formed through any acceptable process, such as, a damascene process, a dual damascene process, or the like.

In some embodiments, the first conductive features 122 may be formed using a damascene process in which a respective first dielectric layer 124 is patterned utilizing a combination of photolithography and etching techniques to form trenches corresponding to the desired pattern of the first conductive features 122. An optional diffusion barrier and/or optional adhesion layer may be deposited, and the trenches may then be filled with a conductive material. Suitable materials for the barrier layer include titanium, titanium nitride, titanium oxide, tantalum, tantalum nitride, titanium oxide, combinations thereof, or the like, and suitable materials for the conductive material include copper, silver, gold, tungsten, aluminum, combinations thereof, or the like. In an embodiment, the first conductive features 122 may be formed by depositing a seed layer of copper or a copper alloy, and filling the trenches by electroplating. A chemical mechanical planarization (CMP) process or the like may be used to remove excess conductive material from a surface of the respective first dielectric layer 124 and to planarize surfaces of the first dielectric layer 124 and the first conductive features 122 for subsequent processing.

FIGS. 21A-21C illustrate five layers of the first conductive features 122 and the first dielectric layers 124 in the front-side interconnect structure 120. However, it should be appreciated that the front-side interconnect structure 120 may comprise any number of first conductive features 122 disposed in any number of first dielectric layers 124. The front-side interconnect structure 120 may be electrically connected to the gate contacts 114 and the source/drain contacts 112 to form functional circuits. In some embodiments, the functional circuits formed by the front-side interconnect structure 120 may comprise logic circuits, memory circuits, image sensor circuits, or the like.

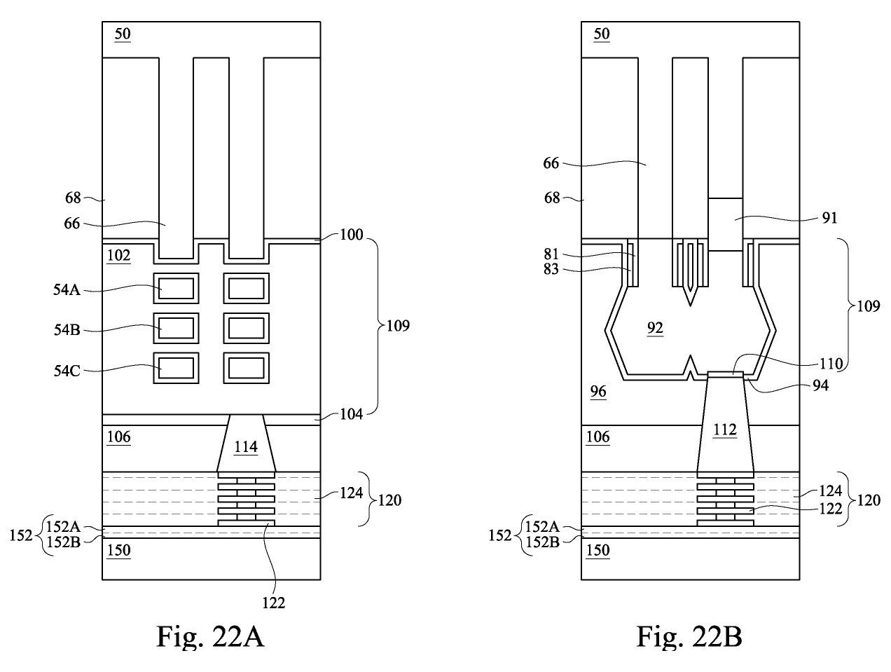

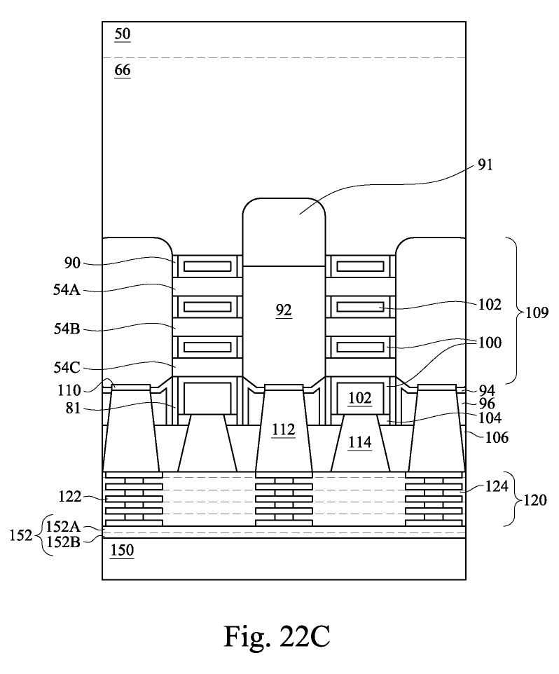

As also illustrated in FIGS. 21A-21C, a first bonding layer 152A may be deposited over the front-side interconnect structure 120. The first bonding layer 152A may facilitate the bonding of a carrier substrate in subsequent processes (see FIGS. 22A-22C) and transfer the heat generated by transistor structures 109 to the carrier substrate during operation as discussed in greater detail below. The first bonding layer 152A may comprise a material suitable for a subsequent dielectric-to-dielectric bonding process and may have a high thermal conductivity, such as a metal oxide. Example materials for the first bonding layer 152A may include titanium oxide, aluminum oxide, nickel oxide, zinc oxide, or the like. The first bonding layer 152A may be deposited by any suitable method, such as PVD, CVD, ALD, or the like. Then a planarization process, such as CMP or the like, may be used to remove excess material from a surface of the first bonding layer 152A and to planarize the surface of the first bonding layer 152A for subsequent processing.

In FIGS. 22A-22C, a carrier substrate 150 is bonded to the front-side interconnect structure 120 by bonding the first bonding layer 152A and a second bonding layer 152B on the carrier substrate 150. The carrier substrate 150 may be a glass carrier substrate, a ceramic carrier substrate, a wafer (e.g., a silicon wafer), or the like. The carrier substrate 150 may provide structural support during subsequent processes and in the completed device. The second bonding layer 152B may comprise a material suitable for a dielectric-to-dielectric bonding process and may have a high thermal conductivity, such as a metal oxide. Example materials for the second bonding layer 152B may include titanium oxide, aluminum oxide, nickel oxide, zinc oxide, or the like. In some embodiments, the first bonding layer 152A and the second bonding layer 152B may comprise a same material. The second bonding layer 152B may be deposited by a similar method as described with respect to the first bonding layer 152A. Then, a planarization process, such as CMP or the like, may be used to remove excess material from a surface of the second bonding layer 152B and to planarize the surface of the second bonding layer 152B for subsequent processing.

The dielectric-to-dielectric bonding process may include applying a surface treatment to one or more of the first bonding layer 152A and the second bonding layer 152B. The surface treatment may include a plasma treatment. The plasma treatment may be performed in a vacuum environment. After the plasma treatment, the surface treatment may further include a cleaning process (e.g., a rinse with deionized water or the like) that may be applied to one or more of the bonding layers 152. The carrier substrate 150 is then aligned with the front-side interconnect structure 120 and the two are pressed against each other to initiate a pre-bonding of the carrier substrate 150 to the front-side interconnect structure 120. The pre-bonding may be performed at room temperature (e.g., between about 21° C and about 25° C). After the pre-bonding, an annealing process may be applied by, for example, heating the front-side interconnect structure 120 and the carrier substrate 150 to a temperature of in a range of 150° C to 500˚ C. The annealing process drives the formation of covalent bonds between the first bonding layer 152A and the second bonding layer 152B. Other bonding processes, such as ambient bonding, vacuum bonding, or the like may be used in other embodiments. After bonding, the first bonding layer 152A and the second bonding layer 152B may be collectively referred to as a bonding layer 152.

Further in FIGS. 22A-22C, after the carrier substrate 150 is bonded to the front-side interconnect structure 120, the device may be flipped such that a back-side of the transistor structures 109 faces upwards. The back-side of the transistor structures 109 may refer to a side opposite to the front-side of the transistor structures 109 on which the active devices are formed.

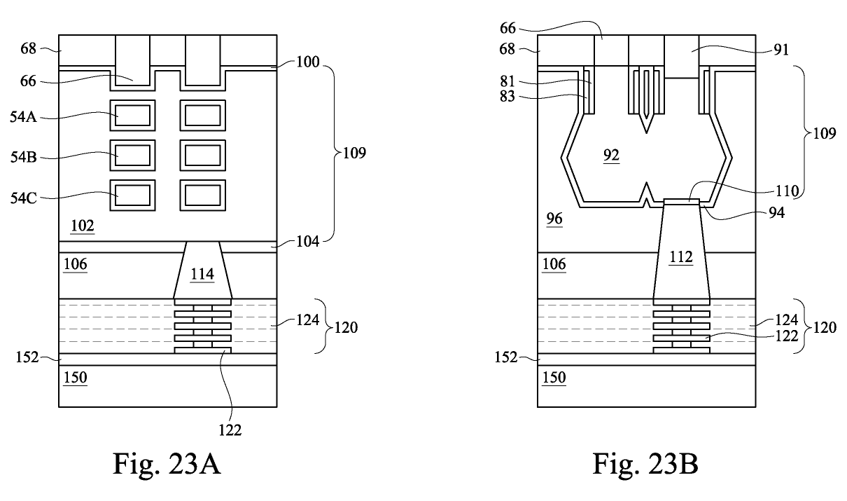

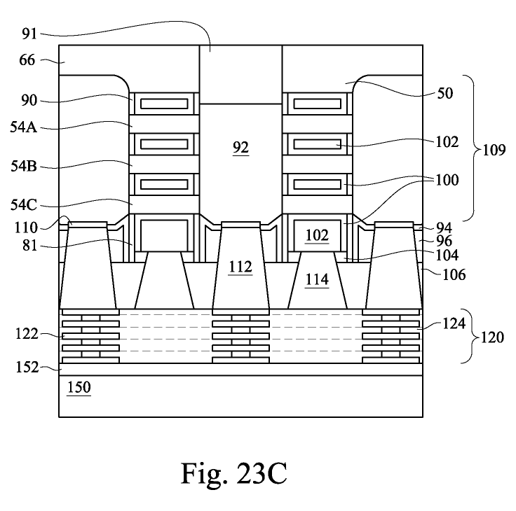

In FIGS. 23A-23C, a thinning process may be applied to the back-side of the substrate 50. The thinning process may comprise a planarization process (e.g., a mechanical grinding, a CMP, or the like), an etch-back process, a combination thereof, or the like. The thinning process may expose surfaces of the semiconductor layer 91 opposite the front-side interconnect structure 120. Further, portions of the fins 66 may remain over the gate structures (e.g., the gate electrodes 102 and the gate dielectric layers 100) and the nanostructures 55 after the thinning process. As illustrated in FIGS. 23A-23C, back-side surfaces of the semiconductor layer 91, the STI regions 68, and the fins 66 may be level with one another following the thinning process.

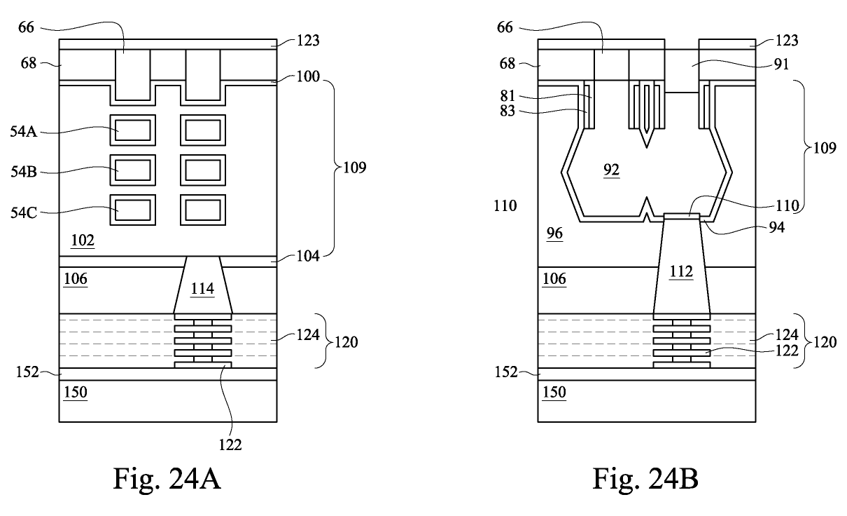

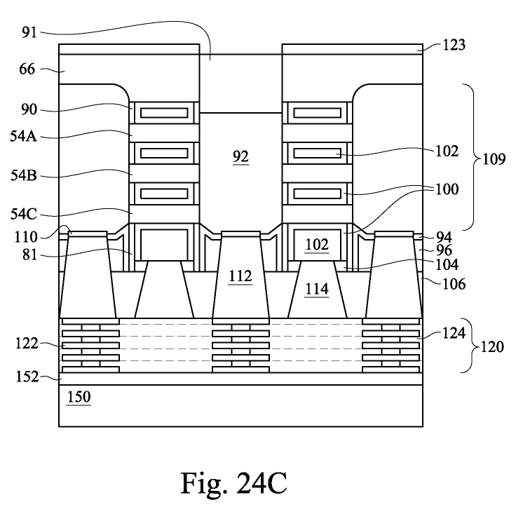

In FIGS. 24A-24C, the second dielectric layer 123 is formed on the back-side surfaces of the fins 66 and the STI regions 68. The semiconductor layer 91 may remain exposed after the second dielectric layer 123 is formed. The second dielectric layer 123 may be used to protect the fins 66 in subsequent processes. The second dielectric layer 123 may comprise a dielectric material such as silicon oxide or the like. The second dielectric layer 123 may be formed by depositing a dielectric layer covering the back-side surfaces of the fins 66, the STI regions 68, and the semiconductor layer 91 by a suitable deposition process, such as CVD, ALD, or the like, and then patterning the dielectric layer to expose the semiconductor layer 91 by a suitable photolithography process.

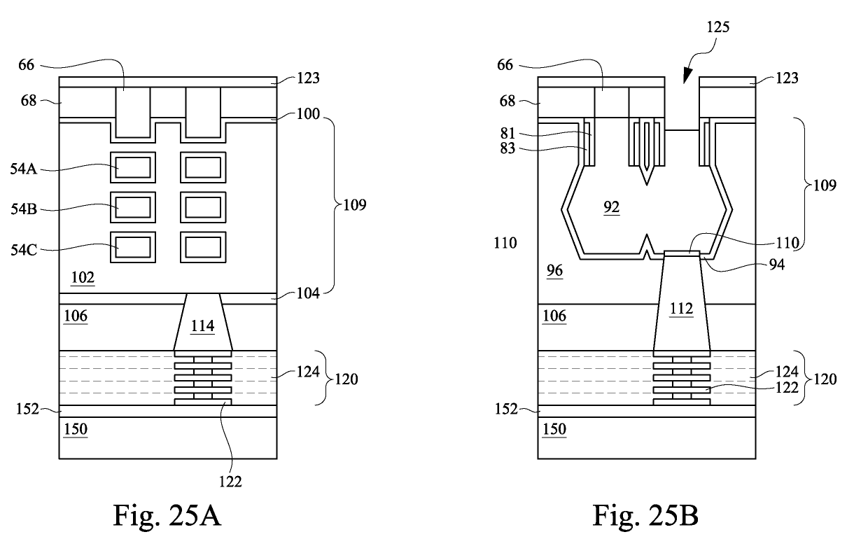

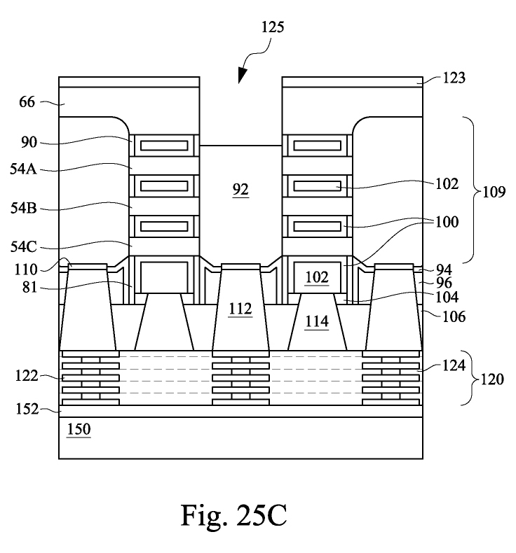

In FIGS. 25A-25C, a fifth recess 125 is formed to expose a back-side surface of the epitaxial source/drain region 92 by removing the semiconductor layer 91. The fifth recess 125 may also expose sidewalls of the fins 66, the STI regions 68, the first spacers 81, the first inner spacers 90, and the second dielectric layer 123. The semiconductor layer 91 may be removed by a suitable etching process, which may be an isotropic etching process. In some embodiments, the etching process is a dry etching process using halogen-based etchants. The etching process may have a high etching selectivity to materials of the semiconductor layer 91. As such, the semiconductor layer 91 may be removed without significantly removing materials of the second dielectric layer 123, the STI regions 68, the first spacers 81, the first inner spacers 90, or the epitaxial source/drain region 92. In the embodiments where the semiconductor layer 91 and the epitaxial source/drain region 92 each comprise silicon germanium, a germanium concentration of each of the semiconductor layer 91 and the epitaxial source/drain region 92 may be varied and selected to achieve such etching selectivity.

In FIGS. 26A-26C, the third spacers 126 are formed on sidewalls of the fins 66, the second dielectric layer 123, the first inner spacers 90, the STI regions 68, the first spacers 81, and the epitaxial source/drain region 92 is partially removed. The third spacers 126 may comprise a dielectric material such as silicon nitride or the like. The third spacers 126 may be formed by depositing a dielectric layer covering the back-side surfaces of the second dielectric layer 123 and the epitaxial source/drain region 92 as well as sidewalls of the various features mentioned above by a suitable deposition process, such as CVD, ALD, or the like, and then etching the dielectric layer to remove the portions of the dielectric layer that cover the second dielectric layer 123 and the epitaxial source/drain region 92 by a suitable etching process. During the etching process, a portion of the epitaxial source/drain region 92 may be also removed, which may result in a concave back-side surface of the epitaxial source/drain region 92. After the etching process, bottom surfaces of the third spacers 126 may also be exposed. In some embodiments, the etching process is a dry etching process using fluorine-based etchants.

In FIGS. 27A-27C, composite layer 127 is formed on the back-side surface of the epitaxial source/drain region 92. FIG. 27D illustrates a region 128 shown in FIG. 27C with more structural details of the composite layer 127. The composite layer 127 may have a high average carrier concentration, which may reduce contact resistance between the epitaxial source/drain region 92 and a subsequently formed conductive contact (e.g., back-side via) over the epitaxial source/drain region 92. The composite layer 127 may be a semiconductor layer with a modulated doping profile. The composite layer 127 may comprise a series of first sublayers 127A and a series of second sublayers 127B arranged in an alternating pattern, wherein one first sublayer 127A may be in contact with the back-side surface of the epitaxial source/drain region 92. The composite layer 127 may be in contact with bottom surfaces of the third spacers 126. FIG. 27D illustrates five first sublayers 127A and five second sublayers 127B in the composite layer 127 as an example, and other numbers of the first sublayers 127A and the second sublayers 127B are contemplated.

In the n-type region 50N of the semiconductor device, the epitaxial source/drain region 92 may comprise silicon and may be doped by n-type dopants, such as phosphorus, arsenic, antimony, or the like. The first sublayers 127A and the second sublayers 127B of the composite layer 127 may comprise a same material with same dopants as the epitaxial source/drain region 92, such as silicon doped with phosphorus, arsenic, antimony, or the like. The epitaxial source/drain region 92 may have a dopant concentration between about 1 x 10¹⁹ atoms/cm³ and about 1 x 10²¹ atoms/cm³. The first sublayers 127A may be highly doped and may have dopant concentrations between about 1 x 10²¹ atoms/cm³ and about 1 x 10²² atoms/cm³. The second sublayers 127B may be lightly doped and may have dopant concentrations between about 1 x 10¹⁵ atoms/cm³ and about 1 x 10²¹ atoms/cm³. The dopant concentrations of the first sublayers 127A may be greater than the dopant concentrations of the second sublayers 127B. The dopant concentration of the epitaxial source/drain region 92 may be less than the dopant concentrations of the first sublayers 127A and greater than the dopant concentrations of the second sublayers 127B. Due to the high dopant concentrations in the first sublayers 127A, the composite layer 127 may have a high average dopant concentration, which may be higher than the dopant concentration of the epitaxial source/drain region 92. As a result, the composite layer 127 may have a high average carrier concentration.

The composite layer 127 may be formed by repeating a cycle of deposition and etching, which may include depositing a first sublayer 127A, depositing a second sublayer 127B, and removing portions of the first sublayer 127A and the second sublayer 127B by an etching process. In some embodiments, the cycle of deposition and etching are repeated five to twenty times to form the composite layer 127. During the first cycle of deposition and etching, when the first sublayer 127A is deposited initially, the first sublayer 127A may comprise an upper portion, which may cover the second dielectric layer 123 and the third spacers 126, and a lower portion, which may cover the epitaxial source/drain region 92. The upper portion of the first sublayer 127A may be amorphous, which may be due to being deposited on dielectric materials, such as the second dielectric layer 123 and the third spacers 126. The lower portion of the first sublayer 127A may be crystalline, which may be due to being deposited on crystalline semiconductor materials, such as the epitaxial source/drain region 92. When the second sublayer 127B is deposited initially, the second sublayer 127B may comprise an upper portion, which may cover the upper portion of the first sublayer 127A (e.g., amorphous portion), and a lower portion, which may cover the lower portion of the first sublayer 127A (e.g., crystalline portion). The upper portion of the second sublayer 127B may be amorphous and the lower portion of the second sublayer 127B may be crystalline.

Then the etching process is performed to selectively remove the upper portions (e.g., amorphous portions) of the first sublayer 127A and the second sublayer 127B while the lower portions (e.g., crystalline portions) of the first sublayer 127A and the second sublayer 127B remain substantially intact. Since the second sublayer 127B has a lower dopant concentration than the first sublayer 127A, the etching selectivity between the crystalline portions and the amorphous portions of the second sublayer 127B may be greater than the etching selectivity between the crystalline portions and the amorphous portions of the first sublayer 127A. As a result, the lower portion (e.g., crystalline portion) of the second sublayer 127B may protect the lower portion (e.g., crystalline portion) of the first sublayer 127A, while the upper portions (e.g., amorphous portions) of the first sublayer 127A and the second sublayer 127B may be both removed during the etching process. Then the cycle of deposition and etching is repeated. During the subsequent cycles of deposition and etching, the upper portions of the first sublayers 127A and the second sublayers 127B may be amorphous after the deposition processes and removed after the etching processes, while the lower portions of the first sublayers 127A and the second sublayers 127B may be crystalline after the deposition processes and substantially intact after the etching processes.

The first sublayer 127A and the second sublayer 127B may be formed by a suitable deposition and doping process, such as CVD with in situ doping, in the n-type region 50N of the semiconductor device while the p-type region 50P of the semiconductor device may be protected by a mask. The process temperature of the deposition and doping process may be less than about 450˚C. Silane, disilane, dichlorosilane, hydrogen chloride, chlorine, and/or the like may be used as precursors for forming the first sublayer 127A and the second sublayer 127B. Phosphine, arsine, stibine, monomethyl silane, and/or the like may be used as precursors for forming the dopants. The etching process may be a dry etching process using hydrogen chloride, chlorine, and/or the like as etchant(s). After the cycles of deposition and etching are completed, the composite layer 127 may have a chlorine concentration between about 1 x 10¹⁴ atoms/cm³ and about 1 x 10¹⁸ atoms/cm³.

In the p-type region 50P of the semiconductor device, the epitaxial source/drain region 92 may comprise silicon germanium and may be doped by p-type dopants, such as boron, gallium, or the like. The first sublayers 127A and the second sublayers 127B of the composite layer 127 may comprise a same material with same dopants as the epitaxial source/drain region 92. The first sublayers 127A and the second sublayers 127B of the composite layer 127 may comprise a different material from the epitaxial source/drain region 92 with same dopants as the epitaxial source/drain region 92. In some embodiments, the first sublayers 127A and the second sublayers 127B comprise silicon germanium doped by p-type dopants, such as boron, gallium, or the like. In some embodiments, the first sublayers 127A comprise germanium doped by p-type dopants, such as boron, gallium, or the like, and the second sublayers 127B comprise silicon germanium doped by p-type dopants, such as boron, gallium, or the like. In some embodiments, the first sublayers 127A comprise silicon germanium doped by p-type dopants, such as boron, gallium, or the like, and the second sublayers 127B comprise silicon doped by p-type dopants, such as boron, gallium, or the like.

The epitaxial source/drain region 92 may have a germanium atomic percent between about 30% and about 50%. The first sublayers 127A may have germanium atomic percent between about 50% and about 100%. The second sublayers 127B may have germanium atomic percent between about 0% and about 50%. The germanium atomic percent of the first sublayers 127A may be greater than the germanium atomic percent of the second sublayers 127B. The germanium atomic percent of the epitaxial source/drain region 92 may be less than the germanium atomic percent of the first sublayers 127A and greater than the germanium atomic percent of the second sublayers 127B.

The epitaxial source/drain region 92 may have a dopant concentration between about 1 x 10¹⁹ atoms/cm³ and about 1 x 10²¹ atoms/cm³. The first sublayers 127A may be lightly doped and may have dopant concentrations between about 1 x 10¹⁵ atoms/cm³ and about 1 x 10²¹ atoms/cm³. The second sublayers 127B may be highly doped and may have dopant concentrations between about 1 x 10²¹ atoms/cm³ and about 1 x 10²² atoms/cm³. The dopant concentrations of the first sublayers 127A may be less than the dopant concentrations of the second sublayers 127B. The dopant concentration of the epitaxial source/drain region 92 may be greater than the dopant concentrations of the first sublayers 127A and less than the dopant concentrations of the second sublayers 127B. Due to the high dopant concentrations in the second sublayers 127B, the composite layer 127 may have a high average dopant concentration, which may be higher than the dopant concentration of the epitaxial source/drain region 92. As a result, the composite layer 127 may have a high average carrier concentration.

The composite layer 127 may be formed by repeating a cycle of deposition and etching, which may include depositing a first sublayer 127A, depositing a second sublayer 127B, and removing portions of the first sublayer 127A and the second sublayer 127B by an etching process. In some embodiments, the cycle of deposition and etching are repeated by five to twenty times to form the composite layer 127. During the first cycle of deposition and etching, when the first sublayer 127A is deposited initially, the first sublayer 127A may comprise an upper portion, which may cover the second dielectric layer 123 and the third spacers 126, and a lower portion, which may cover the epitaxial source/drain region 92. The upper portion of the first sublayer 127A may be amorphous, which may be due to being deposited on dielectric materials, such as the second dielectric layer 123 and the third spacers 126. The lower portion of the first sublayer 127A may be crystalline, which may be due to being deposited on crystalline semiconductor materials, such as the epitaxial source/drain region 92. When the second sublayer 127B is deposited initially, the second sublayer 127B may comprise an upper portion, which may cover the upper portion of the first sublayer 127A (e.g., amorphous portion), and a lower portion, which may cover the lower portion of the first sublayer 127A (e.g., crystalline portion). The upper portion of the second sublayer 127B may be amorphous and the lower portion of the second sublayer 127B may be crystalline.

Then the etching process is performed to selectively remove the upper portions (e.g., amorphous portions) of the first sublayer 127A and the second sublayer 127B while the lower portions (e.g., crystalline portions) of the first sublayer 127A and the second sublayer 127B remain substantially intact. Since the second sublayer 127B has a lower germanium atomic percent than the first sublayer 127A, the etching selectivity between the crystalline portions and the amorphous portions of the second sublayer 127B may be greater than the etching selectivity between the crystalline portions and the amorphous portions of the first sublayer 127A. As a result, the lower portion (e.g., crystalline portion) of the second sublayer 127B may protect the lower portion (e.g., crystalline portion) of the first sublayer 127A, while the upper portions (e.g., amorphous portions) of the first sublayer 127A and the second sublayer 127B may be both removed during the etching process. Then the cycle of deposition and etching is repeated. During the subsequent cycles of deposition and etching, the upper portions of the first sublayers 127A and the second sublayers 127B may be amorphous after the deposition processes and removed after the etching processes, while the lower portions of the first sublayers 127A and the second sublayers 127B may be crystalline after the deposition processes and substantially intact after the etching processes.

The first sublayer 127A and the second sublayer 127B may be formed by a suitable deposition and doping process, such as CVD with in situ doping, in the p-type region 50P of the semiconductor device while the n-type region 50N of the semiconductor device may be protected by a mask. During the deposition and doping process, an increase in germanium atomic percent may lead to a decrease in dopant concentration. The process temperature of the deposition and doping process may be less than about 450˚C. Silane, disilane, dichlorosilane, germane, germanium tetrachloride, hydrogen chloride, chlorine, and/or the like may be used as precursors for forming the first sublayer 127A and the second sublayer 127B. Diborane, boron trichloride, trimethylgallium, and/or the like may be used as precursors for forming the dopants. The etching process may be a dry etching process using hydrogen chloride, chlorine, and/or the like as etchant(s). After the cycles of deposition and etching are completed, the composite layer 127 may have a chlorine concentration between about 1 x 10¹⁴ atoms/cm³ and about 1 x 10¹⁸ atoms/cm³.

In FIG. 28A, a plot of dopant concentration against location in the composite layer 127 in the n-type region 50N of the semiconductor device is shown, which may demonstrate the modulated doping profile of the composite layer 127. The location measurements of the plot may be taken along the Y axis or the Z axis of the composite layer 127 shown on FIG. 27D, and the plot described below may apply to cross-sections along both the Y axis and the Z axis. A representative first sublayer 127A and a representative second sublayer 127B are shown by dashed lines on the location axis of the plot. The first sublayers 127A may have a thickness T1 less than about 7.5 nm and the second sublayers 127B may have a thickness T2 less than about 7.5 nm. In some embodiments, in the n-type region 50N, the thickness T1 is larger than the thickness T2. Peaks and corresponding ramps before and after the peaks of the plot may represent the first sublayers 127A. The peaks may present the core portions of the first sublayers 127A with high dopant concentrations. The peaks may have a thickness T3 less than about 5 nm. Valleys and corresponding ramps before and after the valleys of the plot may represent the second sublayers 127B. The valleys may present the core portions of the second sublayers 127B with low dopant concentrations. The valleys may have a thickness T4 less than about 5 nm. A start of the plot on the location axis may represent an interface between the epitaxial source/drain region 92 and the first sublayer 127A of the composite layer 127. An end of the plot on the location axis may represent a top surface of the composite layer 127, which may be a second sublayer 127B.

In FIG. 28B, a plot of dopant concentration against location in the composite layer 127 in the p-type region 50P of the semiconductor device is shown, which may demonstrate the modulated doping profile of the composite layer 127. The location measurements of the plot may be taken along the Y axis or the Z axis of the composite layer 127 shown on FIG. 27D, and the plot described below may apply to cross-sections along both the Y axis and the Z axis. A representative first sublayer 127A and a representative second sublayer 127B are shown by dashed lines on the location axis of the plot. The first sublayers 127A may have the thickness T1 less than about 7.5 nm and the second sublayers 127B may have the thickness T2 less than about 7.5 nm. In some embodiments, in the p-type region 50P, the thickness T2 is larger than the thickness T1. Valleys and corresponding ramps before and after the valleys of the plot may represent the first sublayers 127A. The valleys may present the core portions of the first sublayers 127A with low dopant concentrations. The valleys may have the thickness T3 less than about 5 nm. Peaks and corresponding ramps before and after the peaks of the plot may represent the second sublayers 127B. The peaks may present the core portions of the second sublayers 127B with high dopant concentrations. The peaks may have a thickness T4 less than about 5 nm. The start of the plot on the location axis may represent the interface between the epitaxial source/drain region 92 and the first sublayer 127A of the composite layer 127. The end of the plot on the location axis may represent the top surface of the composite layer 127, which may be a second sublayer 127B.

The plots in FIGS. 28A and 28B show substantially flat peaks and valleys as examples. In some embodiments, the peaks and valleys may be tilted, which have slopes greater than 10 nm/decade corresponding increases or decreases of the dopant concentration. The plots in FIGS. 28A and 28B show substantially the same dopant concentrations of the peaks and substantially the same dopant concentrations of the valleys as examples. In some embodiments, the dopant concentrations of the peaks and the dopant concentrations of the valleys gradually increase from the start to the end of the plot on the location axis. In some embodiments, the dopant concentrations of the peaks and the dopant concentrations of the valleys gradually decrease from the start to the end of the plot on the location axis.

In FIG. 28C, a plot of germanium atomic percent against location in the composite layer 127 in the p-type region 50P of the semiconductor device is shown. The germanium atomic percent in the first sublayers 127A and the second sublayers 127B may be inversely proportional to the dopant concentrations in the same first sublayers 127A and second sublayers 127B. The location measurements of the plot may be taken along the Y axis or the Z axis of the composite layer 127 shown on FIG. 27D, and the plot described below may apply to cross-sections along both the Y axis and the Z axis. A representative first sublayer 127A and a representative second sublayer 127B are shown by dashed lines on the location axis of the plot. The first sublayers 127A may have the thickness T1 less than about 7.5 nm and the second sublayers 127B may have the thickness T2 less than about 7.5 nm. Peaks and corresponding ramps before and after the peaks of the plot may represent the first sublayers 127A. The peaks may present the core portions of the first sublayers 127A with high germanium atomic percent. The peaks may have the thickness T3 less than about 5 nm. Valleys and corresponding ramps before and after the valleys of the plot may represent the second sublayers 127B. The valleys may present the core portions of the second sublayers 127B with low germanium atomic percent. The valleys may have the thickness T4 less than about 5 nm. A start of the plot on the location axis may represent the interface between the epitaxial source/drain region 92 and the first sublayer 127A of the composite layer 127. An end of the plot on the location axis may represent the top surface of the composite layer 127, which may be a second sublayer 127B.

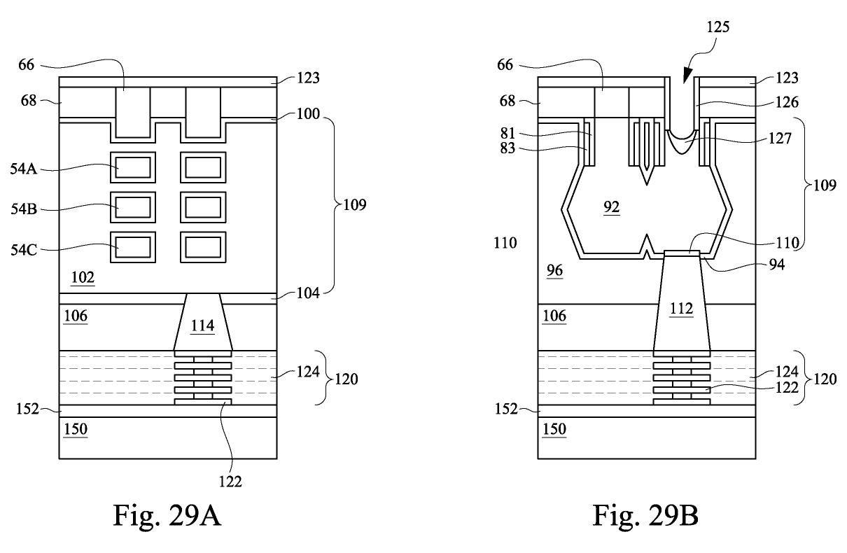

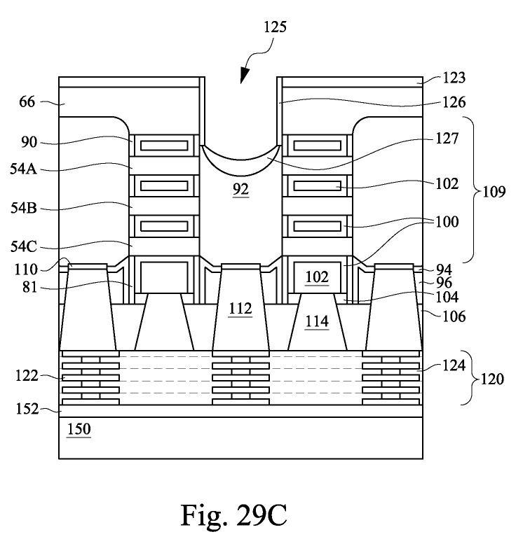

In FIGS. 29A-29C, an upper portion of the composite layer 127 is recessed to form a concave upper surface, thereby improving overall film quality and increasing contact area with a subsequently formed silicide region. The removal of the upper portion of the composite layer may be done by a suitable etching process, such as a drying etching process using fluorine-based etchants. During the etching process, the upper portion of the composite layer 127 may be removed without significantly removing the second dielectric layer 123 and the third spacers 126. After the etching process, the remaining portions of the top surface of the composite layer 127, which may be in contact with the third spacers 126, may be completely covered by the third spacers 126, and the composite layer 127 may have a concave upper surface disposed underneath the top surface.

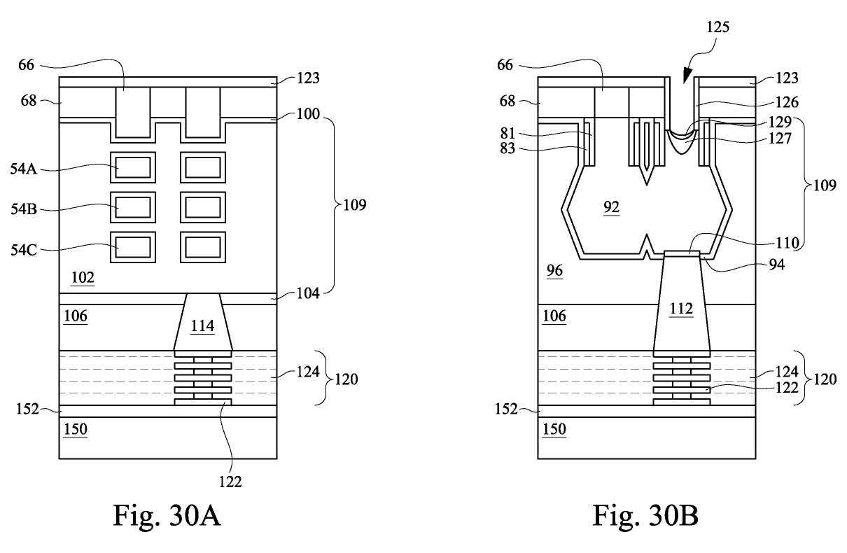

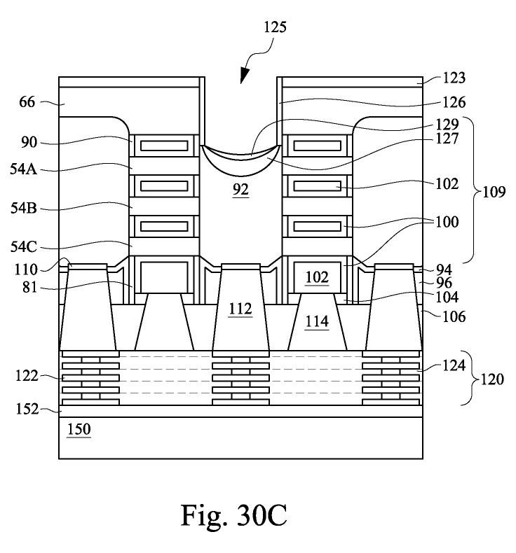

In FIGS. 30A-30C, second silicide region 129 are formed on the composite layer 127 in the fifth recess 125. The second silicide region 129 may be formed of a same or similar material and formed by a same or similar process to the first silicide regions 110 as described above with respect to FIGS. 19A-19C. The thermal annealing process that forms the second silicide region 129 may utilize a lower temperature than the thermal annealing process that forms the first silicide regions 110. A portion of the composite layer 127 near the upper surface may be converted to the second silicide region 129, which may have may have a concave upper surface.

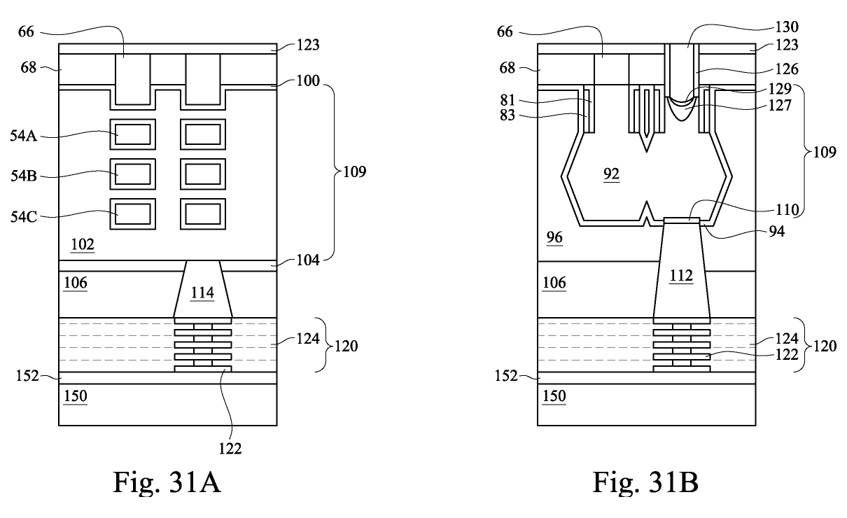

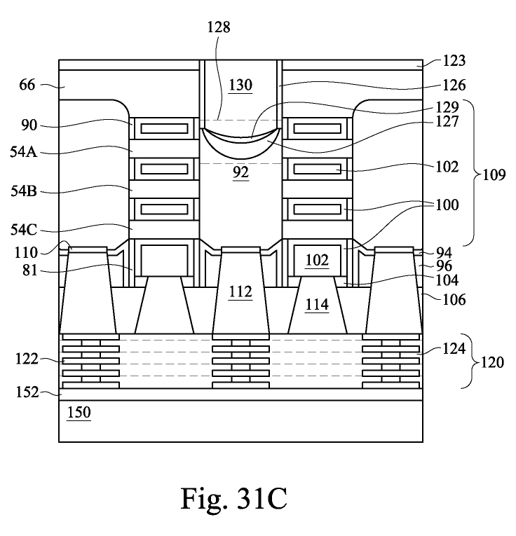

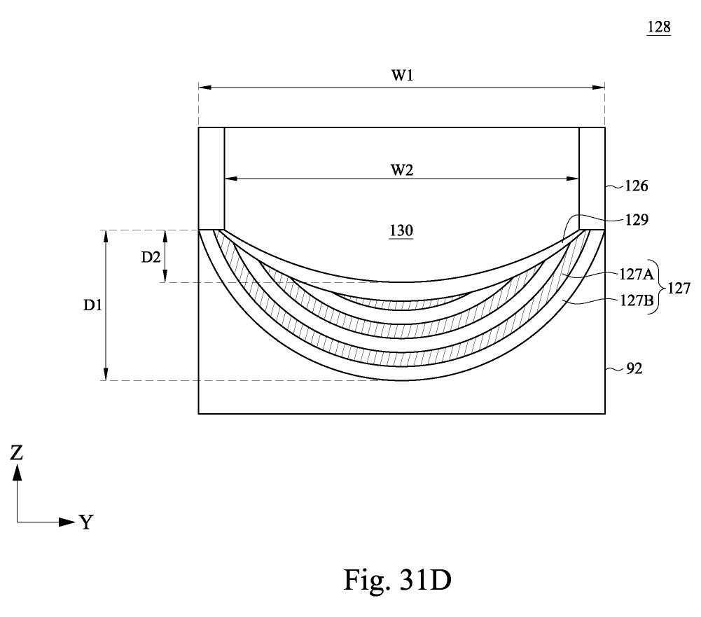

In FIGS. 31A-31D, back-side via 130 is formed in the fifth recess 125. FIG. 31D illustrates the region 128 shown in FIG. 31C with more structural details of the composite layer 127. The back-side via 130 may extend on inner sidewalls of the third spacers 126. The back-side via 130 may extend through the fins 66 and the STI regions 68 and may be electrically connected to the epitaxial source/drain region 92 by the second silicide region 129 and the composite layer 127. Due to the high average dopant concentration and the high average carrier concentration of the composite layer 127, the contact resistance between the epitaxial source/drain region 92 and the back-side via 130 may be reduced, thereby improving the performance of the semiconductor device.

The composite layer 127 may have width W1 between about 5 nm and about 50 nm. The back-side via 130 may have width W2 between about 5 nm and about 40 nm. The width W2 may be less than the width W1. The composite layer 127 may have a depth D1 between about 5 nm and about 40 nm. The depth D1 may be a vertical distance along a Z direction shown in FIG. 31D between the bottom surfaces of the third spacers 126 and a bottom surface of the composite layer 127. The back-side via 130 may have a depth D2 less than about 10 nm. The depth D2 may be a vertical distance along the Z direction shown in FIG. 31D between the bottom surfaces of the third spacers 126 and a bottom surface of the back-side via 130. The depth D2 may be less than the depth D1. The back-side via 130 may be formed of a same or similar material and formed by a same or similar process to the source/drain contacts 112 as described above with respect to FIGS. 20A-20C.

The description above discloses embodiments where the composite layer 127 is formed between one epitaxial source/drain region 92 and one back-side via 130 at the back-sides of the transistor structures 109 as an example. In some embodiments, the composite layers 127 are formed between more than one epitaxial source/drain regions 92 and corresponding back-side vias 130 at the back-sides of the transistor structures 109. In some embodiments, the composite layer(s) 127 are formed between one or more epitaxial source/drain regions 92 and corresponding source/drain contact(s) 112 at the front-sides of the transistor structures 109. In some embodiments, the composite layer(s) 127 are formed between the one or more epitaxial source/drain regions 92 and the corresponding back-side via(s) 130 at the back-sides of the transistor structures 109 as well as between the one or more epitaxial source/drain regions 92 and the corresponding source/drain contact(s) 112 at the front-sides of the transistor structures 109. In such embodiments, the first silicide region(s) 110 may be disposed between the composite layer(s) 127 and the source/drain contact(s) 112.

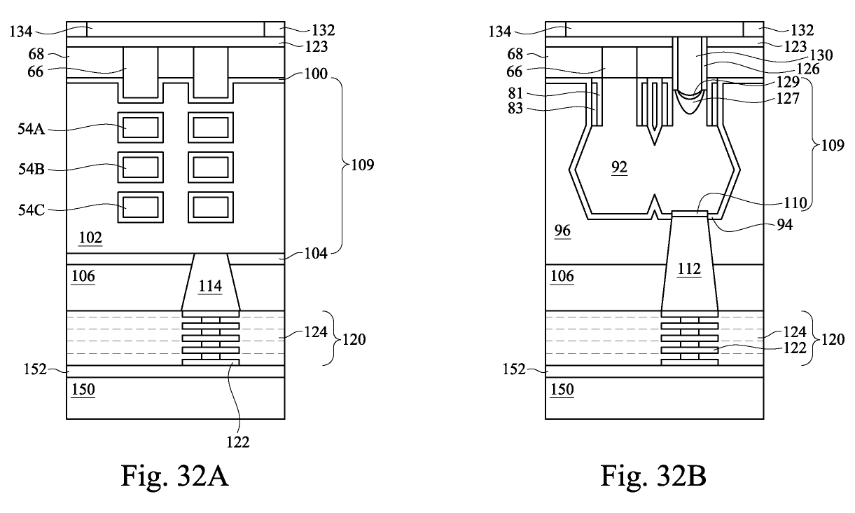

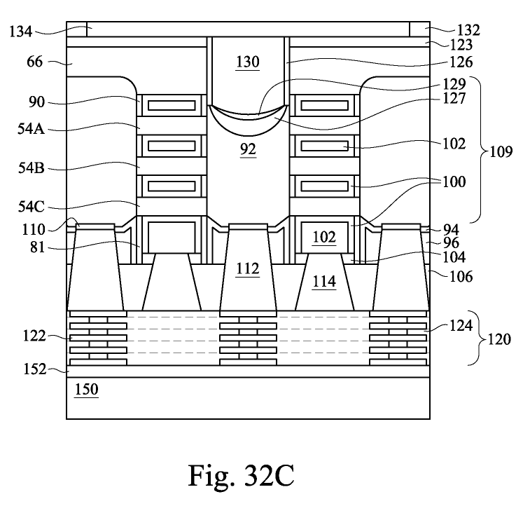

In FIGS. 32A-32C, a third dielectric layer 132 and conductive lines 134 are formed over the second dielectric layer 123, the third spacers 126, and the back-side via 130. The third dielectric layer 132 may be formed of a dielectric material such as PSG, BSG, BPSG, USG, or the like, and may be formed by a suitable deposition method, such as CVD, ALD, or the like.

The conductive lines 134 are formed in the third dielectric layer 132. Forming the conductive lines 134 may include patterning recesses in the third dielectric layer 132 using a combination of photolithography and etching processes, for example. A pattern of the recesses in the third dielectric layer 132 may correspond to a pattern of the conductive lines 134. The conductive lines 134 are then formed by depositing a conductive material in the recesses. In some embodiments, the conductive lines 134 comprise a metal layer, which may be a single layer or a composite layer comprising a plurality of sub-layers formed of different materials. In some embodiments, the conductive lines 134 comprise copper, aluminum, cobalt, tungsten, titanium, tantalum, ruthenium, or the like. An optional diffusion barrier and/or optional adhesion layer may be deposited prior to filling the recesses with the conductive material. Suitable materials for the barrier layer/adhesion layer include titanium, titanium nitride, titanium oxide, tantalum, tantalum nitride, titanium oxide, or the like. The conductive lines 134 may be formed using, for example, CVD, ALD, PVD, plating or the like. The conductive lines 134 are physically and electrically connected to the epitaxial source/drain regions 92 by the back-side vias 130 and the second silicide regions 129. A planarization process (e.g., a CMP, a grinding, an etch-back, or the like) may be performed to remove excess portions of the conductive lines 134 formed over the third dielectric layer 132.

In some embodiments, the conductive lines 134 are power rails, which are conductive lines that electrically connect the epitaxial source/drain regions 92 to a reference voltage, a supply voltage, or the like. By placing power rails on a back-side of the resulting semiconductor device rather than on a front-side of the semiconductor device, advantages may be achieved. For example, a gate density of the nano-FETs and/or interconnect density of the front-side interconnect structure 120 may be increased. Further, the back-side of the semiconductor device may accommodate wider power rails, reducing resistance and increasing efficiency of power delivery to the nano-FETs.

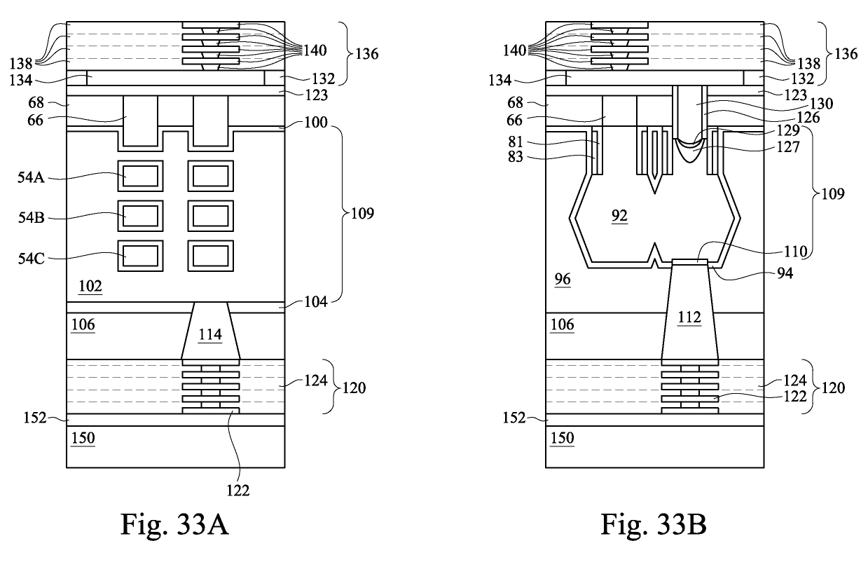

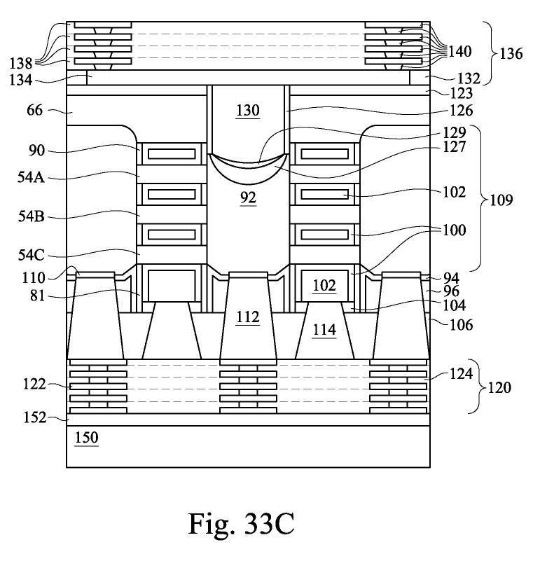

In FIGS. 33A-33C, fourth dielectric layers 138 and second conductive features 140 are formed on the third dielectric layer 132 and the conductive lines 134. The second conductive features 140 may include routing lines (e.g., for routing to and from subsequently formed contact pads and external connectors) in the fourth dielectric layers 138. The fourth dielectric layers 138 may be formed of similar materials using similar processes as the first dielectric layers 124, and the second conductive features 140 may be formed of similar materials using similar processes as the first conductive features 122. The second conductive features 140 may further be patterned to include one or more embedded passive devices such as, resistors, capacitors, inductors, or the like. The embedded passive devices may be integrated with the conductive lines 134 (e.g., the power rail) to provide circuits (e.g., power circuits) on the back-side of the nano-FETs. The third dielectric layer 132, the conductive lines 134, the fourth dielectric layers 138, and the second conductive features 140 may be collectively referred to the back-side interconnect structure 136, which may be on a back-side of the device layer in which transistor structures 109 are disposed (e.g., a side of the transistor structures opposite the gate electrodes 102).

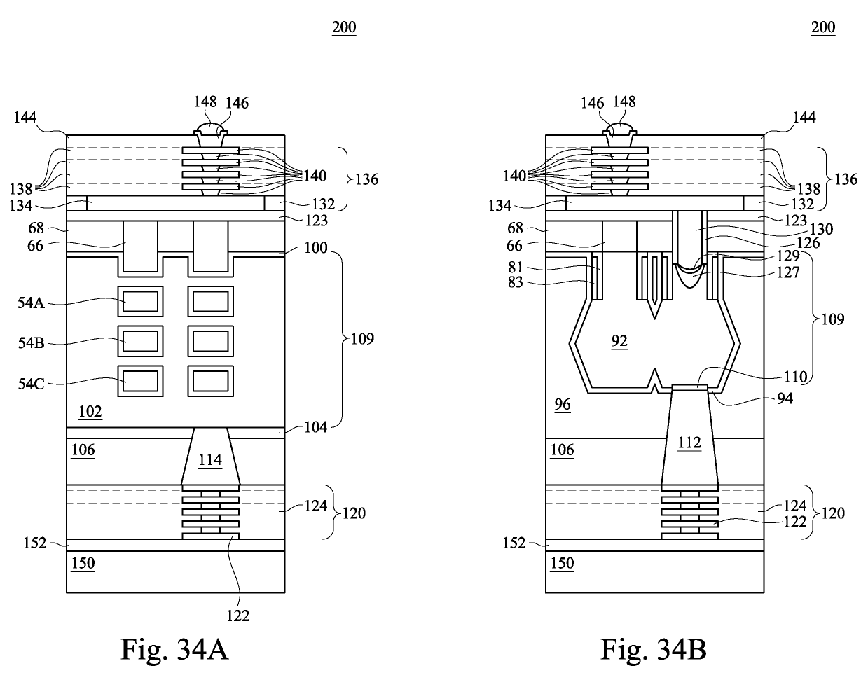

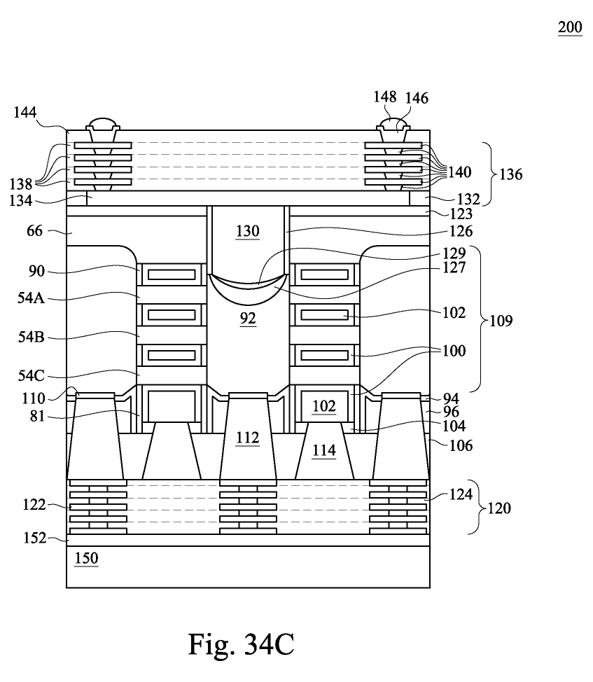

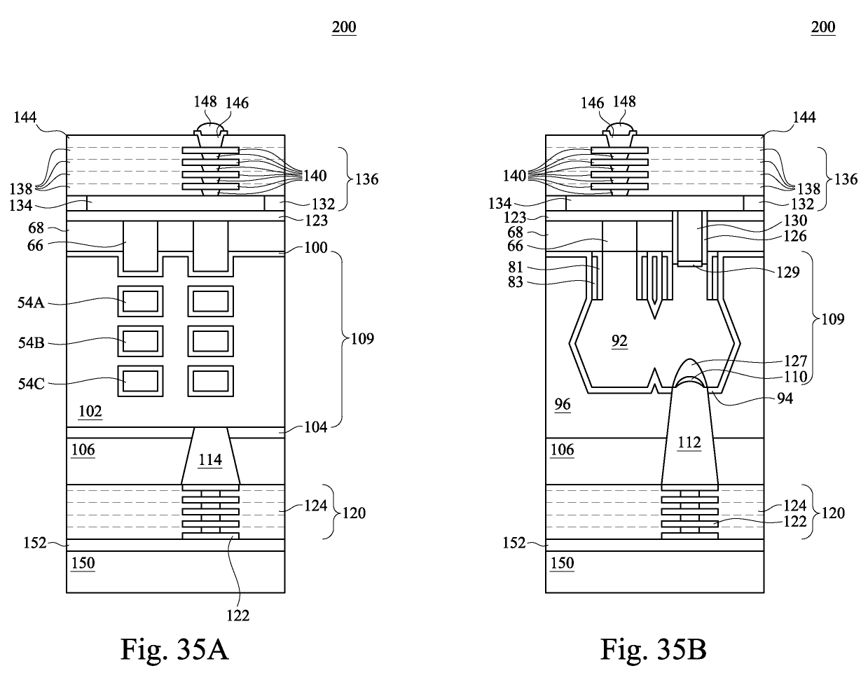

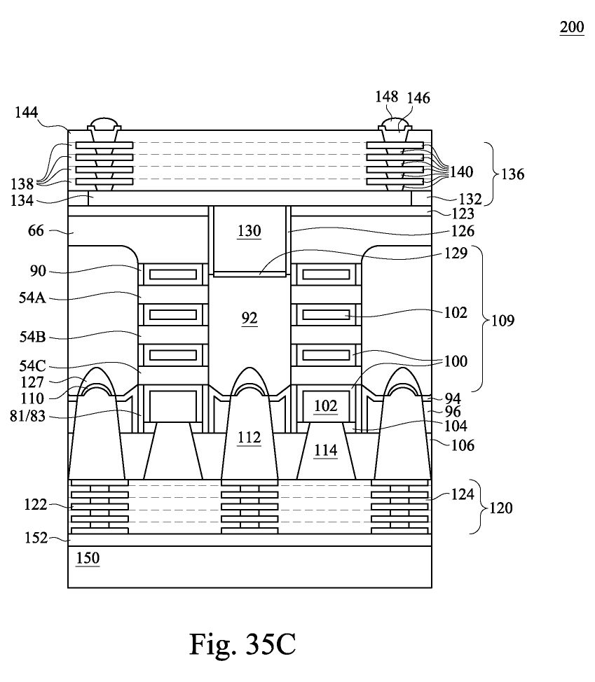

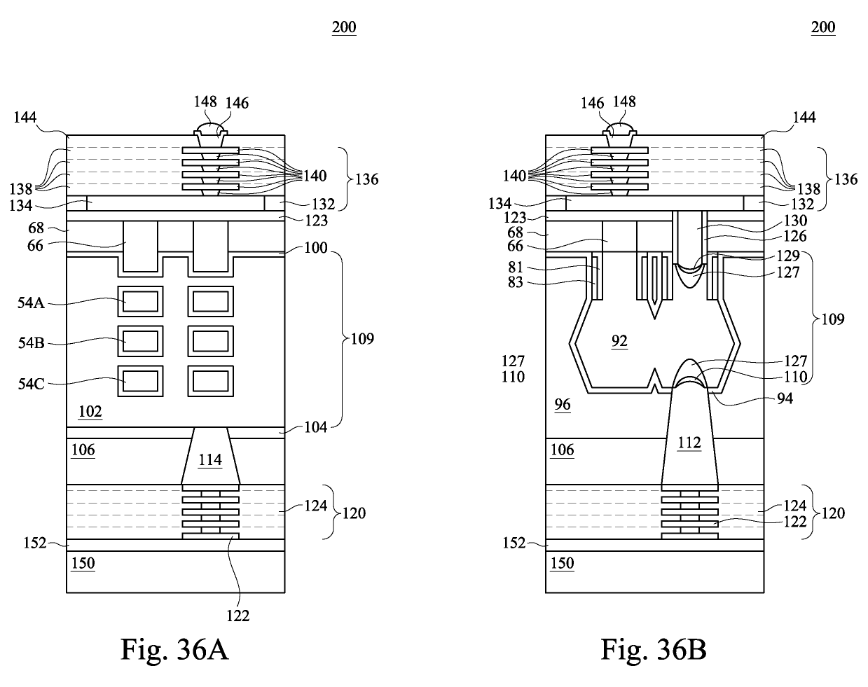

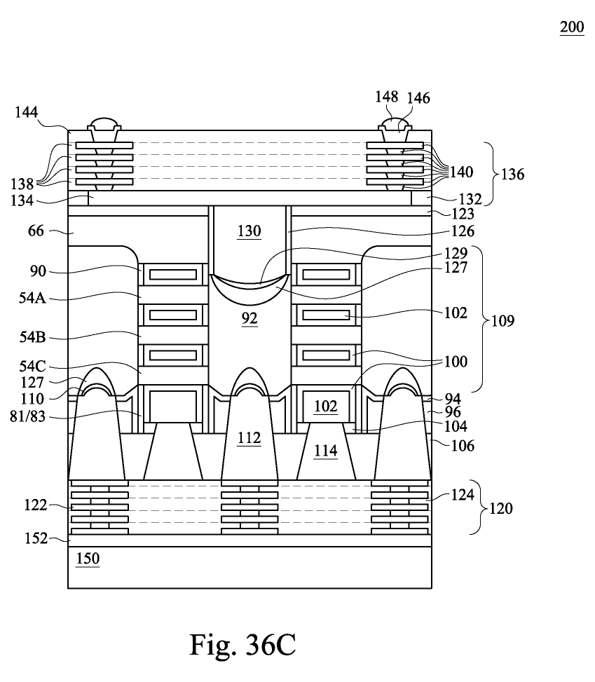

In FIGS. 34A-34C, a passivation layer 144, UBMs 146, and external connectors 148 are formed over the back-side interconnect structure 136. The structure shown in FIGS. 34A-34C, including the front-side interconnect structure 120, the device layer comprising the transistor structures 109, and the back-side interconnect structure 136 may be referred to a semiconductor device 200. The semiconductor device 200 may be referred to as a SPR device. The passivation layer 144 may comprise polymers such as PBO, polyimide, BCB, or the like. Alternatively, the passivation layer 144 may include non-organic dielectric materials such as silicon oxide, silicon nitride, silicon carbide, silicon oxynitride, or the like. The passivation layer 144 may be deposited by, for example, CVD, PVD, ALD, or the like.

The UBMs 146 are formed through the passivation layer 144 to the second conductive features 140 in the back-side interconnect structure 136 and external connectors 148 are formed on the UBMs 146. The UBMs 146 may comprise one or more layers of copper, nickel, gold, or the like, which are formed by a plating process, or the like. The external connectors 148 (e.g., solder balls) are formed on the UBMs 146. The formation of the external connectors 148 may include placing solder balls on exposed portions of the UBMs 146 and reflowing the solder balls. In some embodiments, the formation of the external connectors 148 includes performing a plating step to form solder regions over the topmost conductive lines 140C and then reflowing the solder regions. The UBMs 146 and the external connectors 148 may be used to provide input/output connections to other electrical components, such as, other device dies, redistribution structures, printed circuit boards (PCBs), motherboards, or the like. The UBMs 146 and the external connectors 148 may also be referred to as back-side input/output pads that may provide signal, supply voltage, and/or ground connections to the nano-FETs described above.

FIGS. 35A-36C show embodiments of the semiconductor device 200, similar to the embodiments shown in FIGS. 34A-34C, where like reference numerals refer to like features formed by like processes. FIGS. 35A and 36A illustrate cross-sectional views along the reference cross-section A-A’ illustrated in FIG. 1. FIGS. 35B and 36B illustrate cross-sectional views along the reference cross-section B-B’ illustrated in FIG. 1. FIGS. 35C and 36C illustrate cross-sectional views along the reference cross-section C-C’ illustrated in FIG. 1. In the embodiments shown in FIGS. 35A-35C, the composite layers 127 are formed between the epitaxial source/drain regions 92 and the source/drain contacts 112 at the front-sides of the transistor structures 109. The first silicide regions 110 may be disposed between the composite layers 127 and the source/drain contacts 112. The second silicide region 129 may be in contact with the epitaxial source/drain region 92 at the back-sides of the transistor structures 109. In the embodiments shown in FIGS. 36A-36C, the composite layers 127 are formed between the epitaxial source/drain region 92 and the back-side via 130 at the back-sides of the transistor structures 109 as well as between the epitaxial source/drain regions 92 and the source/drain contacts 112 at the front-sides of the transistor structures 109. The first silicide regions 110 may be disposed between the composite layers 127 and the source/drain contacts 112.

The embodiments of the present disclosure have some advantageous features. By utilizing the deposition and doping methods described above to form a composite layer 127 with a modulated doping profile, the composite layer 127 may have the high average dopant concentration and the high average carrier concentration in both n-type region 50N and the p-type region 50P of the semiconductor device 200, the contact resistance between the epitaxial source/drain region 92 and the back-side via 130 and/or the source/drain contacts 112 may be reduced. As a result, the performance of the semiconductor device 200 may be improved.

In an embodiment, a device includes a source/drain region; a composite layer on the source/drain region, wherein the composite layer has a modulated doping profile, and wherein the composite layer includes: a first sublayer on the source/drain region, wherein the first sublayer includes a first semiconductor material and a first dopant with a first dopant concentration; and a second sublayer, wherein the first sublayer is between the second sublayer and the source/drain region, wherein the second sublayer includes a second semiconductor material and a second dopant with a second dopant concentration, wherein the second dopant is same as the first dopant, and wherein the second dopant concentration is different from the first dopant concentration; and a conductive contact over the composite layer, wherein the conductive contact is electrically connected to the source/drain region by the composite layer. In an embodiment, the second semiconductor material is same as the first semiconductor material. In an embodiment, the source/drain region includes a third semiconductor material and a third dopant with a third dopant concentration, wherein the third semiconductor material is same as the first semiconductor material and the second semiconductor material, wherein the third dopant is same as the first dopant and the second dopant, and wherein the third dopant concentration is between the first dopant concentration and the second dopant concentration. In an embodiment, the first dopant and the second dopant are a same n-type dopant to the first semiconductor material and the second semiconductor material, and wherein the first dopant concentration is greater than the second dopant concentration. In an embodiment, the first dopant and the second dopant are a same p-type dopant to the first semiconductor material and the second semiconductor material, and wherein the first dopant concentration is less than the second dopant concentration. In an embodiment, the first semiconductor material is silicon germanium with a first germanium atomic percent, wherein the second semiconductor material is silicon germanium with a second germanium atomic percent, and wherein the first germanium atomic percent is greater than the second germanium atomic percent. In an embodiment, the composite layer further includes: a third sublayer, wherein the second sublayer is between the first sublayer and the third sublayer, wherein the third sublayer includes the first semiconductor material and the first dopant with a third dopant concentration, and wherein the third dopant concentration is different from the second dopant concentration; and a fourth sublayer, wherein the third sublayer is between the second sublayer and the fourth sublayer, wherein the fourth sublayer includes the second semiconductor material and the second dopant with a fourth dopant concentration, and wherein the fourth dopant concentration is different from the third dopant concentration.

In an embodiment, a device includes a source/drain region; a composite layer on the source/drain region, wherein the composite layer includes highly doped layers and lightly doped layers arranged in an alternating pattern, wherein the highly doped layers includes a first sublayer, wherein the first sublayer includes a first semiconductor material and a first dopant with a first dopant concentration, wherein the lightly doped layers includes a second sublayer over the first sublayer, wherein the second sublayer includes a second semiconductor material and a second dopant with a second dopant concentration, wherein the second dopant is same as the first dopant, and wherein the second dopant concentration is less than the first dopant concentration; and a conductive contact over the composite layer, wherein the conductive contact is electrically connected to the source/drain region by the composite layer. In an embodiment, the first dopant and the second dopant are a same n-type dopant to the first semiconductor material and the second semiconductor material, and wherein the first sublayer is in contact with the source/drain region. In an embodiment, the first dopant and the second dopant are a same p-type dopant to the first semiconductor material and the second semiconductor material, and wherein the second sublayer is in contact with the source/drain region. In an embodiment, source/drain region includes a third dopant with a third dopant concentration, wherein the third dopant is same as the first dopant and the second dopant, and wherein the third dopant concentration is greater than the second dopant concentration and less than the first dopant concentration. In an embodiment, the composite layer includes a higher chlorine concentration than the source/drain region. In an embodiment, the device further includes a silicide layer disposed between the composite layer and the conductive contact.

In an embodiment, a method includes forming a source/drain region; forming a dielectric layer over the source/drain region; forming a composite layer on a surface of the source/drain region, wherein the composite layer has a modulated doping profile, and wherein forming the composite layer includes: forming a first semiconductor layer, wherein an upper portion of the first semiconductor layer is formed on a sidewall of the dielectric layer and a lower portion of the first semiconductor layer is formed on the surface of the source/drain region and, wherein the first semiconductor layer includes a first semiconductor material and a first dopant with a first dopant concentration; forming a second semiconductor layer, wherein an upper portion of the second semiconductor layer is formed on the upper portion of the first semiconductor layer and a lower portion of the second semiconductor layer is formed on the lower portion of the first semiconductor layer, wherein the second semiconductor layer includes a second semiconductor material and a second dopant with a second dopant concentration, wherein the second dopant is same as the first dopant, and wherein the second dopant concentration is different from the first dopant concentration; and selectively removing the upper portion of the first semiconductor layer and the upper portion of the second semiconductor layer by a first etching process, wherein the lower portion of the first semiconductor layer and the lower portion of the second semiconductor layer remain the surface of the source/drain region after the first etching process; and forming a conductive contact over the composite layer, wherein the conductive contact is in contact with the sidewall of the dielectric layer. In an embodiment, the upper portion of the first semiconductor layer and the upper portion of the second semiconductor layer are amorphous, and wherein the lower portion of the first semiconductor layer and the lower portion of the second semiconductor layer are crystalline. In an embodiment, the first etching process uses a chlorine-based etchant. In an embodiment, the first dopant and the second dopant are a same n-type dopant to the first semiconductor material and the second semiconductor material, and wherein the first dopant concentration is greater than the second dopant concentration. In an embodiment, the first dopant and the second dopant are a same p-type dopant to the first semiconductor material and the second semiconductor material, and wherein the first dopant concentration is less than the second dopant concentration. In an embodiment, the first semiconductor material is silicon germanium with a first composition, wherein the second semiconductor material is silicon germanium with a second composition, and wherein the first composition includes more germanium than the second composition. In an embodiment, the composite layer has a modulated germanium atomic percent profile.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a source/drain region;
a composite layer on the source/drain region, the composite layer comprising a series of first sublayers and a series of second sublayers arranged in an alternating pattern, a first sublayer of the series of first sublayers comprising a first semiconductor material and a first dopant with a first dopant concentration, a second sublayer of the series of second sublayers comprising a second semiconductor material and the first dopant with a second dopant concentration different from the first dopant concentration, wherein the composite layer has a chlorine concentration greater than a chlorine concentration of the source/drain region; and
a conductive contact over the composite layer, wherein the conductive contact is electrically connected to the source/drain region by the composite layer.

2. The semiconductor device of claim 1, wherein the first dopant is an n-type dopant, and the first dopant concentration is greater than the second dopant concentration.

3. The semiconductor device of claim 1, wherein the first dopant is a p-type dopant, and the first dopant concentration is less than the second dopant concentration.

4. The semiconductor device of claim 3, wherein the first semiconductor material is silicon germanium with a first germanium atomic percent, the second semiconductor material is silicon germanium with a second germanium atomic percent, and the first germanium atomic percent is greater than the second germanium atomic percent.

5. The semiconductor device of claim 1, wherein the source/drain region comprises the first dopant with a third dopant concentration, and the third dopant concentration is between the first dopant concentration and the second dopant concentration.

6. The semiconductor device of claim 1, further comprising a silicide region between the composite layer and the conductive contact.

7. The semiconductor device of claim 1, wherein the conductive contact comprises a back-side via, and the composite layer is on a back-side surface of the source/drain region.

8. The semiconductor device of claim 1, wherein the chlorine concentration of the composite layer is between 1 x 1014 atoms/cm3 and 1 x 1018 atoms/cm3.

9. A method comprising:
forming a source/drain region;
forming a dielectric layer over the source/drain region;
depositing a semiconductor layer, wherein an upper portion of the semiconductor layer is formed on a sidewall of the dielectric layer and is amorphous, and a lower portion of the semiconductor layer is formed on a surface of the source/drain region and is crystalline, the semiconductor layer comprising a semiconductor material and a dopant;
selectively removing the upper portion of the semiconductor layer by an etching process, wherein the lower portion of the semiconductor layer remains on the surface of the source/drain region after the etching process to form a contact layer; and
forming a conductive contact on the contact layer and on the sidewall of the dielectric layer, wherein the conductive contact is electrically connected to the source/drain region by the contact layer.

10. The method of claim 9, wherein the etching process is a dry etching process using a chlorine-based etchant.

11. The method of claim 9, wherein depositing the semiconductor layer comprises chemical vapor deposition with in situ doping.

12. The method of claim 9, wherein the contact layer has a chlorine concentration greater than a chlorine concentration of the source/drain region.

13. The method of claim 9, wherein depositing the semiconductor layer comprises forming a first sublayer and forming a second sublayer over the first sublayer, and a dopant concentration of the second sublayer is different from a dopant concentration of the first sublayer.

14. The method of claim 9, further comprising forming a silicide region on the contact layer before forming the conductive contact.

15. The method of claim 9, wherein the conductive contact is a back-side via.

16. A method comprising:
forming a source/drain region;
forming a dielectric layer over the source/drain region;
forming a composite layer on a surface of the source/drain region, wherein forming the composite layer comprises:
depositing a first sublayer, wherein an upper portion of the first sublayer is formed on a sidewall of the dielectric layer and is amorphous, and a lower portion of the first sublayer is formed on the surface of the source/drain region and is crystalline, the first sublayer comprising a first semiconductor material and a first dopant with a first dopant concentration;
depositing a second sublayer, wherein an upper portion of the second sublayer is formed on the upper portion of the first sublayer and is amorphous, and a lower portion of the second sublayer is formed on the lower portion of the first sublayer and is crystalline, the second sublayer comprising a second semiconductor material and the first dopant with a second dopant concentration less than the first dopant concentration; and
performing an etching process that removes the upper portion of the first sublayer and the upper portion of the second sublayer, wherein an etching selectivity between the lower portion of the second sublayer and the upper portion of the second sublayer is greater than an etching selectivity between the lower portion of the first sublayer and the upper portion of the first sublayer such that the lower portion of the second sublayer protects the lower portion of the first sublayer during the etching process, and wherein the lower portion of the first sublayer and the lower portion of the second sublayer remain on the surface of the source/drain region after the etching process; and
forming a conductive contact over the composite layer, wherein the conductive contact is electrically connected to the source/drain region by the composite layer.

17. The method of claim 16, wherein the first dopant is an n-type dopant to the first semiconductor material and the second semiconductor material.

18. The method of claim 16, wherein depositing the first sublayer, depositing the second sublayer, and performing the etching process are repeated a plurality of times such that the composite layer comprises a series of first sublayers and a series of second sublayers arranged in an alternating pattern.

19. The method of claim 16, wherein the etching process is a dry etching process using a chlorine-based etchant.

20. The method of claim 16, further comprising forming a silicide region on the composite layer, wherein the conductive contact is a back-side via electrically connected to the source/drain region by the silicide region and the composite layer.
